(19) United States
(12) Patent Application Publication
(10) Pub. No.: US 2007/0054051 A1
(43) Pub. Date: Mar. 8, 2007

(54) Deposition device

(75) Inventors: Yasuyuki Arai, Atsugi (JP); Shunpei Yamazaki, Tokyo (JP)

Correspondence Address: COOK, ALEX, McFARRON, MANZO,;CUMMINGS & MEHLER, LTD., SUITE 2850, 200 WEST ADAMS STREET, CHICAGO, IL, 60606, US

(73) Assignee: Semiconductor Energy Laboratory Co., Ltd.

(21) Appl. No.: 11/510,996

(22) Filed: Aug. 28, 2006

(30) Foreign Application Priority Data
Sep. 6, 2005 (JP) 2005-258558

(51) Int. Cl. C23C 16/00

(52) U.S. Cl. 427/248.1; 118/726

(57) ABSTRACT

A deposition device provided with an evaporation source which is opposite to a substrate over which a film is deposited and is provided to be capable of moving in accordance with a surface of the substrate and a means for supplying an evaporation material to the evaporation source (evaporation material supply means). The evaporation source is held by a moving means capable of scanning one surface of a substrate over which a film is deposited. The evaporation material supply means uses a method of supplying a powder of an evaporation material by an airflow, a method of aerosolizing material liquid in which an evaporation material is dissolved or dispersed in a solvent to supply, or a method of supplying an evaporation material which is in a rod shape, a wire shape, a powdery form, and in a state of being attached to a flexible film by a mechanical mechanism.

### BACKGROUND OF THE INVENTION

1. Field of the Invention

The present invention relates to a deposition device for forming a film by evaporation. In particular, the present invention relates to a deposition device which is used for manufacturing a display device utilizing electroluminescence.

2. Description of the Related Art

An electroluminescence element (hereinafter, referred to as an “EL element”) mainly using an organic material is manufactured by evaporating a film containing a light-emitting medium. A film formation by evaporation has been conventionally known widely. As a deposition device used for manufacturing an organic EL element, there is a structure in which each layer constituting the organic EL element is continuously deposited while keeping a vacuum atmosphere in separate vacuum chambers (for example, see Patent Document 1: Japanese Patent Application Laid-Open No. H10-241858 (Pages 6 and 7, FIG. 4)).

An evaporation device is disclosed, in which a substrate and an evaporation mask are placed over a substrate holding means, a distance between an evaporation source and the substrate is decreased to 30 cm or less, and the evaporation source is transferred in an X direction or a Y direction to perform deposition (for example, see Patent Document 2: Japanese Patent Application Laid-Open No. 2004-063454 (Pages 5 to 7, FIG. 1)).

In these deposition devises, deposition of an EL layer in an EL element is performed by a resistance heating method. A resistance heating method refers to a method by which an evaporation source formed from metal or ceramic is filled with an evaporation material, and is evaporated or sublimated by heating under reduced pressure to form a film. A conventional evaporation source cannot control temperature precipitously; therefore, attachment of the evaporation material to a substrate is required to be controlled by opening and closing of a shutter while continuously evaporating the evaporation material.

### SUMMARY OF THE INVENTION

A size of a glass substrate which is used in manufacturing an electroluminescence display device has been made large. For example, glass substrates having a size of 1500 mm×1800 mm in a sixth generation, a size of 1870 mm×2200 mm in a seventh generation, and a size of 2160 mm×2400 mm in an eighth generation will be introduced to a manufacturing line.

However, in depositing an EL layer, the amount of evaporation material which can be filled to an evaporation source is limited, and it becomes increasingly harder to continuously process multiple large-sized substrates. That is, in order to continuously evaporate the EL layer to a large-sized glass substrate, a large amount of evaporation materials are required; however, there are limits to a size of a crucible which is an evaporation source, and the sufficient amount of evaporation material cannot be filled. Therefore, there is a problem that an evaporation operation has to be stopped for each several substrates so that an evaporation source is filled with an evaporation material. Evaporation requires predetermined time until a temperature of the evaporation source becomes stable, and a material which evaporates during that time is wasted; therefore a yield of the material is decreased, which results in decrease in throughput.

In view of the foregoing problems, it is an object of the present invention to provide a deposition device capable of enhancing utilization efficiency of an evaporation material and continuously performing evaporation to a large-sized substrate.

One feature of the present invention is a deposition device provided with an evaporation source which is opposite to a substrate over which a film is deposited and capable of moving corresponding to a surface of the substrate, and a means for supplying an evaporation material to the evaporation source (evaporation material supply means).

The evaporation source is provided with a roll-like object and a heating means so that an evaporation material is heated in the roll-like object. Various methods can be applied to the heating means, such as a method of heating by applying a current to the roll-like object, a method of heating by radiation heat, a method of heating by resistance heating, and a method of heating by induction heating.

The evaporation source is held by a moving means capable of scanning a surface of a substrate over which a film is deposited. One or a plurality of evaporation sources is held in the moving means. The evaporation source and the evaporation material supply means may be integrated, or the evaporation material supply means may be fixed to the evaporation source which is set to be capable of moving. In the latter case, the evaporation source and the evaporation material supply means are connected to each other by a material supply tube having an inner diameter through which an evaporation material in a predetermined state can pass.

The following methods are included in the evaporation material supply means: a method of supplying a powder of an evaporation material by an airflow, a method of aerosolizing material liquid in which an evaporation material is dissolved or dispersed in a solvent to supply, a method of supplying an evaporation material in a rod form, a wire form, a powdery form, and in a state of being attached to a flexible film by a mechanical mechanism.

Another feature of the present invention is a deposition device having an evaporation source which is provided in a treatment chamber capable of keeping a reduced pressure state and is opposite to a substrate over which an evaporation material is deposited; a moving means for moving the evaporation source to scan along a main surface of the substrate; and an evaporation material supply means for supplying an evaporation material, which is connected to the evaporation source.

Another feature of the present invention is a deposition device having an evaporation source which is provided in a treatment chamber capable of keeping a reduced pressure state and is opposite to a substrate over which an evaporation material is deposited, for aerosolizing material liquid in which an evaporation material is dissolved or dispersed in a solvent to evaporate or sublimate a solvent in the aerosol; a moving means for moving the evaporation source to scan along a main surface of the substrate; and an evaporation material supply means for supplying the material liquid, which is connected to the evaporation source.

Another feature of the present invention is a deposition device having an evaporation source which is provided in a treatment chamber capable of keeping a reduced pressure state, is opposite to a substrate over which an evaporation material is deposited, and evaporates or sublimates a powdery evaporation material with an inert gas or a reactive gas; a moving means for scanning the evaporation source along a main surface of the substrate; and an evaporation material supply means for supplying a powdery evaporation material with an active gas or an reactive gas, which is connected to the evaporation source.

Another feature of the present invention is a deposition device having an evaporation source which is provided in a treatment chamber capable of keeping a reduced pressure state, is opposite to a substrate over which an evaporation material is deposited, and evaporates or sublimates a powdery evaporation material; a moving means for moving the evaporation source to scan along a main surface of the substrate; and an evaporation material supply means in which a material supply tube is connected to the evaporation source and the powdery evaporation material is continuously supplied by rotating a screw provided in the material supply tube.

Another feature of the present invention is a deposition device having an evaporation source which is provided in a treatment chamber capable of keeping a reduced pressure state and is provided with an opening through which a flexible film to which an evaporation material is attached is continuously discharged; a heating means for emitting an energy beam to the flexible film to which an evaporation material exposed in the opening is attached; and a moving means for moving the evaporation source to scan along a main surface of the substrate.

Another feature of the present invention is a method for manufacturing a display device including steps of providing an evaporation source in a treatment chamber, disposing a substrate in the treatment chamber, and evaporating a material from the evaporation source to deposit the material over the substrate. The relative position of the evaporation source is repeatedly moved with respect to the substrate during the evaporation of the material. A material supply portion is connected to the evaporation source through a material supply tube.

According to the present invention, deposition can be continuously performed uniformly even in a case of a display panel having a large-sized screen. In addition, it is not necessary that an evaporation source is supplied with an evaporation material every time an evaporation material is used up; therefore, throughput can be improved.

### BRIEF DESCRIPTION OF DRAWINGS

In the accompanying drawings:

FIG. 1 is a view explaining a structure of a deposition device relating to Embodiment Mode 1;

FIG. 2 is a view explaining an internal structure of a deposition device relating to Embodiment Mode 1;

FIG. 3 is a view explaining an internal structure of a deposition device relating to Embodiment Mode 2;

FIG. 4 is a view explaining an internal structure of a deposition device relating to Embodiment Mode 3;

FIG. 5 is a view explaining an internal structure of a deposition device relating to Embodiment Mode 3;

FIG. 6 is a view showing an example of an evaporation source and an evaporation material supply portion provided for a deposition treatment chamber of a deposition device relating to Embodiment Mode 4;

FIG. 7 is a view showing an example of an evaporation source and an evaporation material supply portion provided for a deposition treatment chamber of a deposition device relating to Embodiment Mode 5;

FIG. 8 is a view showing an example of an evaporation source and an evaporation material supply portion provided for a deposition treatment chamber of a deposition device relating to Embodiment Mode 6;

FIGS. 9A and 9B are views each showing an example of an evaporation source and an evaporation material supply portion provided for a deposition treatment chamber of a deposition device relating to Embodiment Mode 7;

FIG. 10 is a view explaining a structure of an EL element relating to Embodiment Mode 7;

FIG. 11 is a view explaining a structure of a light-emitting device relating to Embodiment Mode 9;

FIGS. 12A and 12B are views each explaining a structure of a light-emitting device relating to Embodiment Mode 9;

FIG. 13 is a view explaining a structure of a light-emitting device relating to Embodiment Mode 9;

FIGS. 14A and 14B are views each explaining a structure of a light-emitting device relating to Embodiment Mode 10;

FIG. 15 is a view explaining a structure of a light-emitting device relating to Embodiment Mode 11;

FIG. 16 is a view explaining a structure of a light-emitting device relating to Embodiment Mode 11;

FIGS. 17A and 17B are cross-sectional views each explaining a manufacturing process of a light-emitting device relating to Embodiment Mode 11;

FIG. 18 is a top view explaining a manufacturing process of a light-emitting device relating to Embodiment Mode 11 (corresponding to FIG. 17A);

FIGS. 19A to 19C are cross-sectional views each explaining a manufacturing process of a light-emitting device relating to Embodiment Mode 11;

FIG. 20 is a top view explaining a manufacturing process of a light-emitting device relating to Embodiment Mode 11 (corresponding to FIG. 19B);

FIGS. 21A to 21C are cross-sectional views each explaining a manufacturing process of a light-emitting device relating to Embodiment Mode 11;

FIG. 22 is a top view explaining a manufacturing process of a light-emitting device relating to Embodiment Mode 11 (corresponding to FIG. 21A);

FIG. 23 is a top view explaining a manufacturing process of a light-emitting device relating to Embodiment Mode 11 (corresponding to FIG. 21C);

FIG. 24 is a cross-sectional view explaining a manufacturing process of a light-emitting device relating to Embodiment Mode 11;

FIGS. 25A to 25C are cross-sectional views each explaining a manufacturing process of a light-emitting device relating to Embodiment Mode 12;

FIG. 26 is a cross-sectional view explaining a manufacturing process of a light-emitting device relating to Embodiment Mode 12;

FIG. 27 is a top view explaining a manufacturing process of a light-emitting device relating to Embodiment Mode 13;

FIG. 28 is an equivalent circuit diagram explaining a manufacturing process of a light-emitting device relating to Embodiment Mode 13;

FIG. 29 is a view explaining a manufacturing process of a light-emitting device relating to Embodiment Mode 14;

FIG. 30 is a view explaining a manufacturing process of a light-emitting device relating to Embodiment Mode 14;

FIG. 31 is a view explaining a deposition method in Embodiment Mode 15;

FIG. 32 is a view explaining a mode of a light-emitting device relating to Embodiment Mode 16;

FIG. 33 is a view explaining a mode of a light-emitting device relating to Embodiment Mode 16;

FIG. 34 is a view explaining a structure of a television device relating to Embodiment Mode 17;

FIG. 35 is a view explaining a structure of a television device relating to Embodiment Mode 17;

FIG. 36 is a view explaining a structure of a cellular phone relating to Embodiment Mode 18; and

FIG. 37 is a view explaining a structure of a cellular phone relating to Embodiment Mode 18.

### DETAILED DESCRIPTION OF THE INVENTION

### Embodiment Mode

Embodiment modes of the present invention will be explained in detail with reference to the accompanying drawings. However, the present invention is not limited to the description below, and it is easily understood by those skilled in the art that the modes and details of the present invention can be modified in various ways without departing from the purpose and the scope of the present invention. Therefore, the present invention is not interpreted as being limited to the description of the embodiment modes to be given below. It is to be noted that, in the structure hereinafter described, the reference numerals denoting the same portions are used in common in different drawings and the repeated description thereof is omitted.

### Embodiment Mode 1

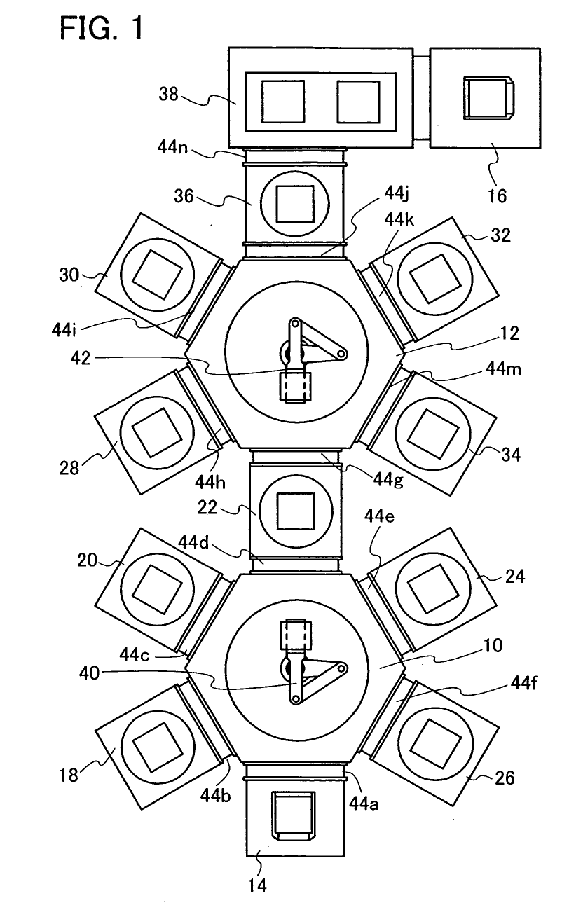

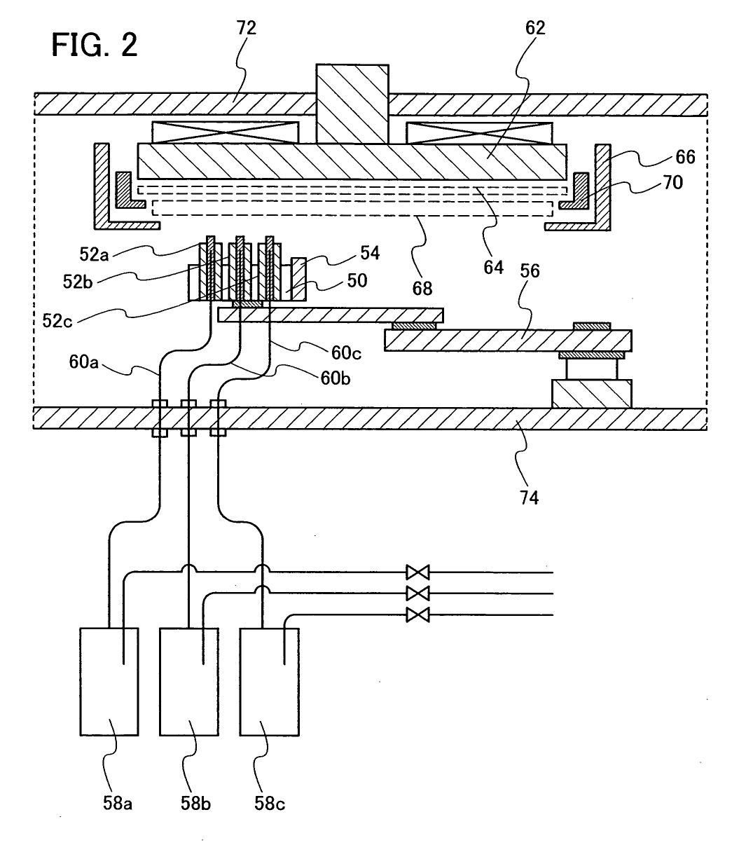

In this embodiment mode, a structure of a deposition device provided with a scanning evaporation source and an evaporation material supply means connected to the scanning evaporation source will be explained with reference to FIGS. 1 and 2.

FIG. 1 shows a structure of a deposition device for forming an EL layer over a substrate. It is to be noted that an EL layer refers to a layer at least partially containing a material exhibiting electroluminescence (electroluminescence refers to a phenomenon in which light is emitted when an electric field is applied to a fluorescent material or a phosphorescent material). The EL layer may be formed of a plurality of layers each having a different function. For example, there is a case where a plurality of layers each having a different function such as a hole injecting/transporting layer, a light-emitting layer, or an electron injecting/transporting layer is contained in the EL layer.

This deposition device includes transfer chambers 10 and 12 each of which connects a plurality of treatment chambers. The treatment chamber includes a load chamber 14 for introducing a substrate, an unload chamber 16 for collecting a substrate, a heat treatment chamber 18, a plasma treatment chamber 26, deposition treatment chambers 20, 22, 24, 28, 30, and 32 for evaporating an EL material, and a deposition treatment chamber 34 for forming a conductive film as one of electrodes of an EL element. Also, gate valves 44a to 44k, 44m and 44n are provided between the transfer chambers and each treatment chamber, and the pressure of each treatment chamber can be independently controlled to prevent mutual contamination between the treatment chambers.

A substrate introduced to the transfer chamber 10 from the load chamber 14 is transferred to a predetermined treatment chamber by an arm transfer means 40 provided to be freely rotatable. The substrate is transferred from one treatment chamber to another treatment chamber by the transfer means 40. The transfer chambers 10 and 12 are connected to each other by the deposition treatment chamber 22, and a substrate is transferred and received by the transfer means 40 and a transfer means 42.

Each treatment chamber connected to the transfer chamber 10 or the transfer chamber 12 is kept at reduced pressure. Therefore, deposition treatment of an EL layer is continuously performed without exposing the substrate to the air in this deposition device. There is a case where a substrate terminated with the deposition treatment of the EL layer deteriorates due to moisture vapor or the like. Therefore, in this deposition device, a sealing treatment chamber 38 for sealing the EL layer before exposing to the air is connected to the transfer chamber 12 in order to keep the quality. Since the sealing treatment chamber 38 is placed under the atmospheric pressure or reduced pressure close to the atmospheric pressure, an intermediate chamber 36 is provided between the transfer chamber 12 and the sealing treatment chamber 38. The intermediate chamber 36 is provided in order to transfer and receive a substrate and alleviate pressure between the chambers

Each of the load chamber, the unload chamber, the transfer chamber, and the deposition treatment chamber is provided with an exhaust means for keeping the chamber at reduced pressure. As the exhaust means, various vacuum pumps such as a dry pump, a turbo-molecular pump, and a diffusion pump can be used.

In the deposition device of FIG. 1, the number and structure of the treatment chamber connected to the transfer chambers 10 and 12 can be appropriately combined in accordance with a stacked layer structure of the EL element. An example of a combination of the treatment chambers is shown below.

In the heat treatment chamber 18, degasification treatment is performed first by heating a substrate over which a lower electrode, an insulating partition wall, and the like are formed. In a plasma treatment chamber 26, plasma treatment with a rare gas or oxygen is performed to a surface of the base electrode. This plasma treatment is performed in order to clean a surface, stabilize the surface state, and stabilize a physical or chemical state of the surface (for example, work function or the like).

The deposition treatment chamber 20 can be a treatment chamber for forming an electrode buffer layer which is in contact with one of electrodes of an EL element. The electrode buffer layer has a carrier injecting property (a hole injecting property or an electron injecting property) and suppresses a short circuit of the EL element or generation of defects such as a dark spot. Typically, the electrode buffer layer is formed from an organic-inorganic mixture material so as to have resistivity of 5×10⁴ to 1×10⁶ Ωcm with a thickness of 30 to 300 nm. Also, the deposition treatment chamber 24 is a treatment chamber for depositing a hole transporting layer.

A light-emitting layer in an EL element has a different structure depending on a case of mono-color light emission and a case of white color light emission. It is preferable to provide a deposition chamber in the deposition device in accordance with the light emission color. For example, in a case of forming three kinds of EL elements each of which exhibits light with a different light emission color in a display panel, light-emitting layers corresponding to each light emission colors are required to be deposited. In this case, the deposition treatment chambers 22, 28, and 30 can be used for depositing a first light-emitting layer, a second light-emitting layer, and a third light-emitting layer, respectively. By changing the deposition treatment chamber for each light-emitting layer, mutual contamination of different light-emitting materials can be prevented, which results in improvement in throughput of the deposition treatment

Alternatively, three kinds of EL materials each of which exhibits light with a different light emission color may be sequentially evaporated in each of the deposition treatment chambers 22, 28, and 30. In this case, evaporation is performed using a shadow mask and shifting the mask in accordance with a region to be evaporated.

In a case of forming an EL element which exhibits white light emission, light-emitting layers that exhibit light with different colors are vertically stacked from the bottom. In that case, each light-emitting layer can be deposited by sequentially moving an element substrate through the deposition treatment chambers. Alternatively, different light-emitting layers can be continuously deposited in the same deposition treatment chamber.

In the deposition treatment chamber 34, an electrode is formed over the EL layer. Although an electron beam evaporation method or a sputtering method can be applied for forming the electrode, a resistance heating evaporation method is preferably used.

An element substrate where the process up to a formation of an electrode is completed is transferred to the sealing treatment chamber 38 through the intermediate chamber 36. The sealing treatment chamber 38 is filled with an inert gas such as helium, argon, neon, or nitrogen, and is sealed by attaching a sealing plate on a side of the element substrate where the EL layer is formed, under the atmosphere. A space between the element substrate and the sealing substrate may be filled with an inert gas or a resin material in the state of being sealed. By filling the sealing treatment chamber 38 with an inert gas or a resin material, the EL element can be prevented from touching atmospheric air or gas which is corrosive to the EL element and deteriorating. The sealing treatment chamber 38 is provided with a mechanical component such as a dispenser for drawing a sealing material, a fixed stage for fixing the sealing plate to be opposite to the element substrate, or an arm; a dispenser for resin material filling; a spin coater; or the like.

FIG. 2 shows an example of an internal structure of a deposition treatment chamber. The deposition treatment chamber is kept at reduced pressure. In FIG. 2, an interior side interposed between a top plate 72 and a bottom plate 74 corresponds to the inside of the chamber, which is kept at reduced pressure.

One or a plurality of evaporation sources are provided in the treatment chamber. In a case of depositing a plurality of layers each of which has a different composition or a case of co-evaporating a different material, it is preferable to provide a plurality of evaporation sources. In FIG. 2, evaporation sources 52a, 52b, and 52c are set in an evaporation source holder 50. The evaporation source holder 50 is held by a multi-joint arm 56. The multi-joint arm 56 allows the evaporation source holder 50 to be movable within its movable scope with the use of telescopic joints. Also, the evaporation source holder 50 may be provided with a distance sensor 54 and a distance between the evaporation sources 52a, 52b, and 52c and a substrate 64 is monitored so that an optimal distance in evaporation may be controlled. In that case, the multi-joint arm may also be capable of traveling in an up and down direction (Z direction).

The substrate 64 is held by a chuck 70 and fixed to a substrate stage 62. The substrate stage 62 may incorporate a heater so as to heat the substrate 64. A chuck 66 is provided in order to fix a shadow mask 68. The shadow mask 68 is set so as to be between the substrate 64 and the evaporation sources 52a, 52b and 52c. The shadow mask 68 is provided with an opening in accordance with a pattern for forming a film, and is used for a case where an evaporation film is required to be selectively formed over a substrate. In a case where alignment of the shadow mask 68 is required, a camera is set in the treatment chamber and a positioning means which moves in an X-Y-θ direction is provided in the chuck 66; accordingly, positioning can be performed.

An evaporation material supply portion which continuously supplies an evaporation material to an evaporation source is provided in each of the evaporation sources 52a, 52b, and 52c. The material supply portion includes evaporation material supply sources 58a, 58b, and 58c that are placed apart from the evaporation sources 52a, 52b, and 52c, and material supply tubes 60a, 60b, and 60c for connecting the evaporation sources to the evaporation material supply sources. In FIG. 2, the material supply source 58a and the evaporation source 52a are connected to each other by the material supply tube 60a. The same can be said for the material supply source 58b and the evaporation source 52b, and the material supply source 58c and the evaporation source 52c. It is not necessary that, as shown in FIG. 2, the material supply source 58a, 58b, and 58c correspond to the evaporation sources 52a, 52b, and 52c, respectively. A plurality of material supply sources may be connected to one evaporation source, and a plurality of evaporation sources may be connected to one material supply source. In either case, deposition can be continuously performed by supplying an evaporation material to the evaporation source from the material supply source.

The evaporation sources 52a, 52b, and 52c are formed from a material such as ceramic or metal which does not easily react with an evaporation material. The evaporation sources 52a, 52b, and 52c are preferably formed by using a ceramic material such as aluminum nitride or boron nitride. Since the ceramic material does not easily react with an evaporation material containing an organic material and emits little gas as an impurity, an EL layer with high purity can be formed.

Various methods can be applied for supplying an evaporation material to the evaporation sources 52a, 52b and 52c from the material supply sources 58a, 58b and 58c. For example, the following methods can be applied: an airflow transfer method of transferring an evaporation material in a powdery form with a carrier gas; an aerosolizing method of transferring material liquid in which an evaporating material is dissolved or dispersed in a solvent, aerosolizing by an atomizer, and evaporation the solvent in the aerosol; a method of providing a screw in the material supply tube 60 and transferring a powdery evaporation material by rotating the screw; or the like. The evaporation source 52 is provided with a heating means, which evaporates a transferred evaporation material to perform deposition. The evaporation source 52 is fixed to the evaporation source holder 50 to scan inside the treatment chamber by multijoint arm 56; therefore, the material supply tube 60 includes a stiff and narrow tube which can be bent flexibly and does not change the shape even under reduced pressure.

In a case of applying an airflow transfer method or an aerosolizing method, there is a case where a carrier gas is supplied inside the treatment chamber with an evaporation material. An exhaust fan or a vacuum exhaust pump is connected to each of the treatment chambers, and accordingly, the treatment chamber can be kept at atmospheric pressure or pressure lower than that, preferably 133 to 13300 Pa. The pressure can be controlled by filling the deposition treatment chamber with an inert gas such as helium, argon, neon, krypton, xenon, or nitrogen, or supplying the gas (while exhausting the gas at the same time). A deposition treatment chamber for forming an oxide film may be set to be an oxidized atmosphere by introducing a gas such as oxygen or nitrous oxygen. Also, a deposition treatment chamber for evaporating an organic material may be set to be a reduction atmosphere by introducing a gas such as hydrogen. Moreover, a method of providing a screw inside the material supply tube 60 and transferring a powdery evaporation material by rotating the screw, deposition makes it possible to perform deposition while keeping pressure 133 Pa or less by a vacuum pump.

According to the deposition device of this embodiment mode, deposition can be continuously performed uniformly even in a case of a display panel having a large-sized screen. In addition, it is not necessary that the evaporation source is supplied with an evaporation material every time an evaporation material is used up; therefore, throughput can be improved.

### Embodiment Mode 2

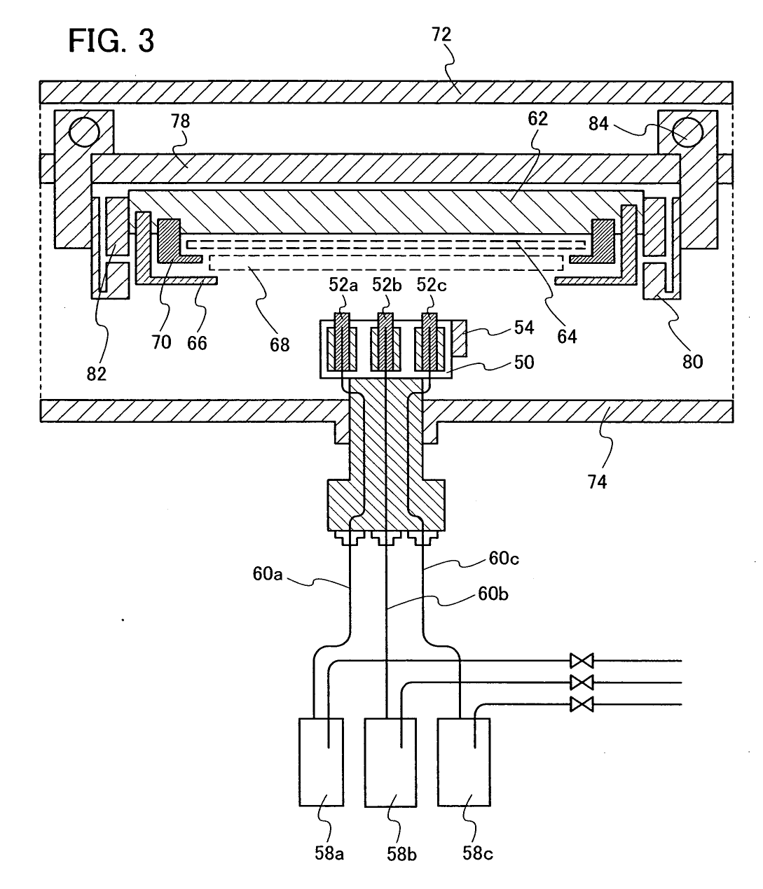

In this embodiment mode, a structure of a deposition treatment chamber where evaporation is performed by fixing an evaporation source and moving a substrate will be explained with reference to FIG. 3.

FIG. 3 shows an internal structure of the deposition treatment chamber. The deposition treatment chamber is constructed so that a reduced pressure state can be kept. A jig or the like for fixing an evaporation source or a substrate is provided in an interior side interposed between a top plate 72 and a bottom plate 74 that are included in the deposition treatment chamber.

Evaporation sources 52a, 52b and 52c provided inside the deposition treatment chamber are the same as the one in Embodiment Mode 1. One or a plurality of evaporation sources can be provided. The evaporation sources 52a, 52b and 52c are attached to an evaporation source holder 50 which is provided on the bottom plate 74 side. Even in a case of fixing a position of the evaporation source 52, a distance sensor 54 for measuring a distance between the evaporation source and the substrate may be provided and a transfer mechanism of moving up and down may be provided so that a distance between the evaporation source 52 and a substrate 64 to be set can be controlled. By controlling the distance between the evaporation sources 52a, 52b and 52c and the substrate 64 to be set, deposition speed or a film thickness distribution can be adjusted.

A substrate stage 62 fixes the substrate 64 over which a film is deposited, by a chuck 70. In this case, a heater may be incorporated in the substrate stage 62 so as to heat the substrate 64. In a case of using a shadow mask 68 in depositing, the shadow mask 68 can be fixed to the substrate stage 62 by a chuck 66 with the substrate 64. A transfer mechanism 82 including a pulley or a gear is provided at an edge of the substrate stage 62 so that the transfer mechanism 82 can move on a first guide rail 80. In addition, the first guide rail 80 is provided with a transfer mechanism 84 such as a pulley or a gear so that the transfer mechanism 84 can move on a second guide rail 78.

An evaporation material supply portion which continuously supplies an evaporation material to an evaporation source is connected to evaporation sources 52a, 52b, and 52c. The material supply portion has evaporation material supply sources 58a, 58b, and 58c that are placed apart from the evaporation sources 52a, 52b, and 52c, and material supply tubes 60a, 60b, and 60c for connecting the evaporation sources to the evaporation material supply sources. The detail of these is the same as Embodiment Mode 1.

According to the deposition device of this embodiment mode, deposition can be continuously performed uniformly even in a case of a display panel having a large-sized screen. In this case, when an outside dimension of a substrate becomes larger, a distance to transfer the substrate is increased, and it is necessary to enlarge the deposition treatment chamber with the distance. In such a case, a plurality of fixed evaporation sources is provided inside the deposition treatment chamber to be appropriately placed in a central part or a peripheral part; accordingly, a transfer distance of the substrate which is necessary for evaporating an entire surface of the substrate can be decreased. In addition, it is not necessary that the evaporation source is supplied with an evaporation material every time an evaporation material is used up; therefore, throughput can be improved.

### Embodiment Mode 3

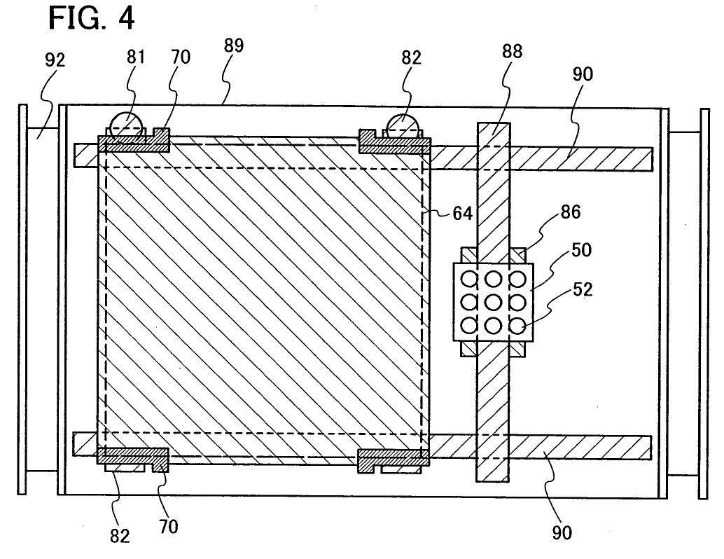

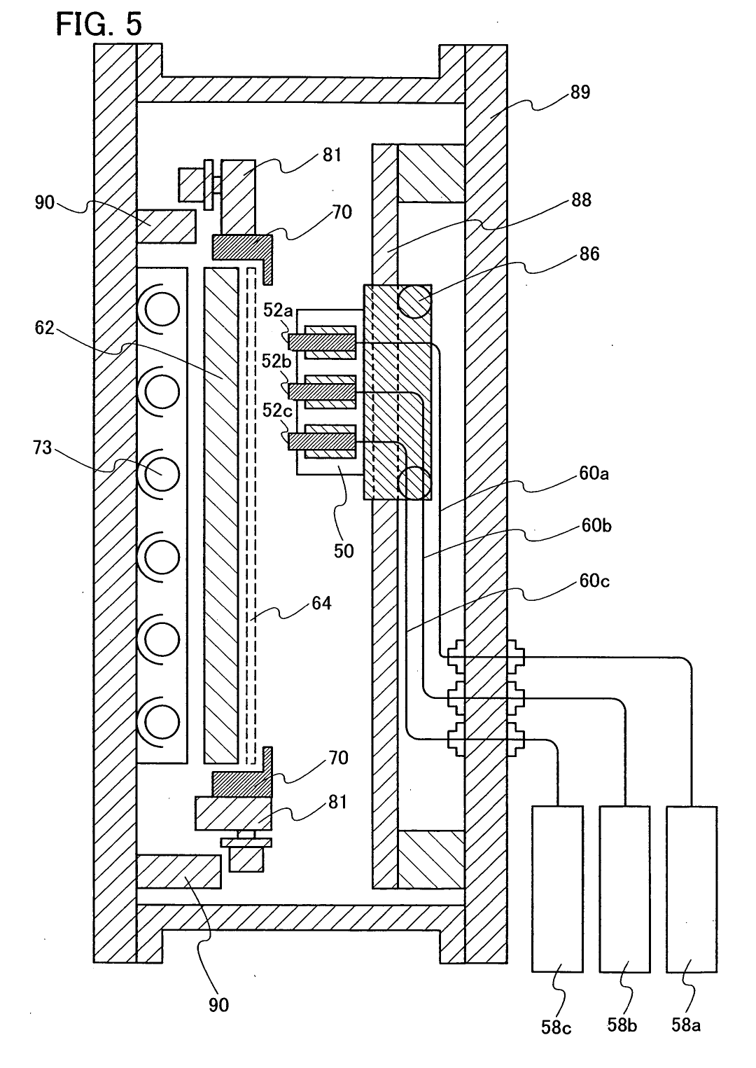

In this embodiment mode, a structure of a deposition treatment chamber in which evaporation is performed by moving both an evaporation source and a substrate will be explained with reference to FIGS. 4 and 5. It is to be noted that FIG. 4 is a front view of a deposition treatment chamber and FIG. 5 is a detail view showing an internal structure of the deposition treatment chamber. The following explanation will be made with reference to both of the drawings.

In FIG. 4, a gate valve 92 is fixed to a deposition treatment chamber 89. A substrate 64 fixed to a transfer table 81 by a chuck 70 is inserted from the gate valve 92, and deposition is performed in a step where the substrate 64 moves inside the deposition treatment chamber 89 on the guide rail 90. By connecting a plurality of such deposition treatment chambers 89 in series, an inline deposition device for forming a plurality of layers of a film can be formed.

In an internal structure shown in FIG. 5, evaporation sources 52a, 52b and 52c provided in a deposition treatment chamber 89 have the same structures as the evaporation sources in Embodiment Mode 2. One or a plurality of evaporation sources can be provided, and the evaporation source is attached to an evaporation source holder 50. The evaporation source holder 50 is provided with a transfer mechanism 86 including a pulley or a gear so as to move up and down by a second guide rail 88. By appropriately controlling transfer speed of a substrate 64 which is transferred by a first guide rail 90 and operation speed of the evaporation source 52 which moves up and down by the second guide rail 88, deposition speed or a film thickness distribution can be adjusted.

A heater 73 may be provided on a side where the substrate 64 is transferred, which is an inner wall of the deposition treatment chamber 89. As the heater 73, a lamp heater, a sheathed heater, or the like can be used. By providing the heater 73, the substrate 64 can be heated, and a substrate temperature at the time of deposition can be controlled.

An evaporation material supply portion which continuously supplies an evaporation material to an evaporation source is connected to evaporation sources 52a, 52b, and 52c. The material supply portion includes evaporation material supply sources 58a, 58b, and 58c that are placed apart from the evaporation sources 52a, 52b, and 52c, and material supply tubes 60a, 60b, and 60c for connecting the evaporation sources to the evaporation material supply sources. The detail of these is the same as Embodiment Mode 1.

According to the deposition device of this embodiment mode, by alternately moving the substrate and the evaporation source, deposition can be continuously performed uniformly even in a case of a display panel having a large-sized screen. In this case, by keeping the substrate in a vertical state or in a state that is inclined at 1 to 30 degrees from the vertical state, the substrate can be stably held even in a case of a large-sized substrate having a side of 1 meter or more, which results in suppression of transfer troubles. In addition, it is not necessary that the evaporation source is supplied with an evaporation material every time an evaporation material is used up; therefore, throughput can be improved.

### Embodiment Mode 4

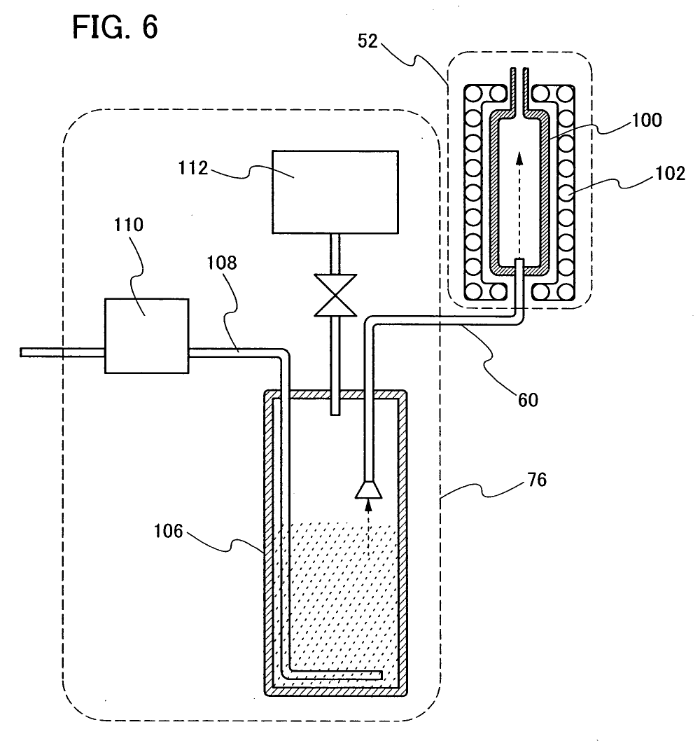

In this embodiment mode, an example of an evaporation source provided in a deposition treatment chamber of a deposition device and an example of an evaporation material supply portion will be explained with reference to FIG. 6. In this embodiment mode, a structure will be shown, in which a powder of an evaporation material is supplied by an airflow current in order to increase utilization efficiency and continuously perform evaporation to a large-sized substrate.

An evaporation source 52 and an evaporation material supply portion 76 are connected to each other by a material supply tube 60. In the evaporation material supply portion 76, an evaporation material storage cell 112 and a gas supply tube 108 are connected to a powder stirring chamber 106. A carrier gas whose amount is controlled by a gas flow controller 110 flows into the powder stirring chamber 106, a powdery evaporation material supplied from the evaporation material storage cell 112 is dispersed, and a carrier gas with a power flows into the evaporation source 52 through the material supply tube 60. As a carrier gas, one or plurality of gasses selected from an inert gas such as helium, argon, krypton, or xenon; a nitrogen gas; and a hydrogen gas can be used.

The evaporation source 52 has a cylinder cell 100 and a heater 102 for heating the cylinder cell 100. The cylinder cell 100 and the material supply tube 60 are connected to each other, and a carrier gas with a powder flows into the cylinder cell 100. The powder which is an evaporation material is heated in the cylinder cell 100 to be vaporized. Then, the powder is emitted with a carrier gas from an opening at one end of the cylinder cell 100. It is preferable that the cylinder cell 100 be formed from ceramic such as alumina, boron nitride, or silicon nitride in order to suppress catalysis with an evaporation material containing an organic substance.

A temperature of the cylinder cell 100 which is heated by the heater 102 is set to be a temperature by which a powdery evaporation material to be supplied can be evaporated or sublimated. In this case, the temperature may be set so as to increase from a connecting portion of the material supply tube 60 toward an opening (an opening through which vapor is emitted) in the cylinder cell 100. By making the cylinder cell 100 have such a temperature gradient, an evaporation material can be efficiently consumed without clogging.

By applying the evaporation material supply portion of this embodiment mode to the evaporation sources in the deposition devices of Embodiment Modes 1 to 3, deposition can be continuously performed uniformly even in a case of a large-sized substrate. In addition, it is not necessary that the evaporation source is supplied with an evaporation material every time an evaporation material is used up; therefore, throughput can be improved.

### Embodiment Mode 5

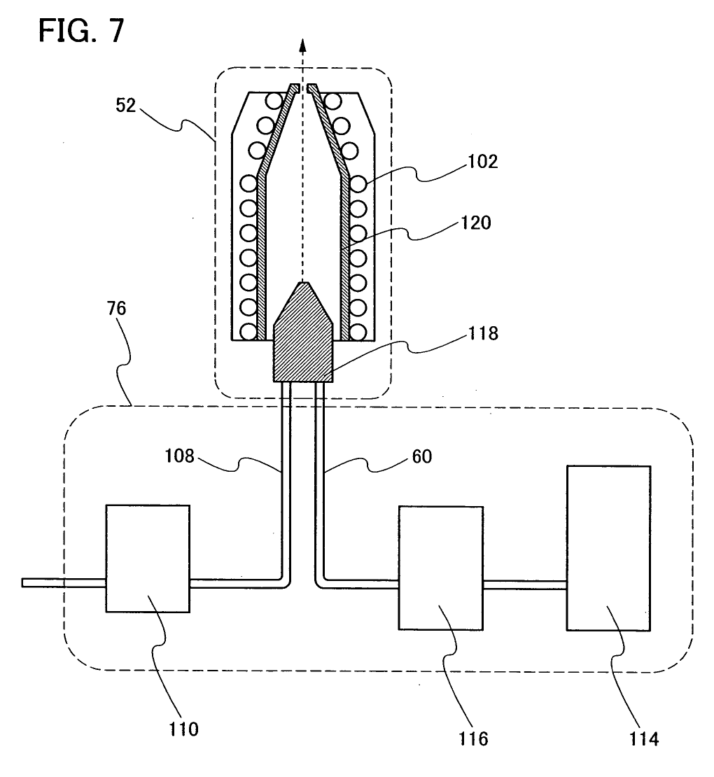

In this embodiment mode, an example of an evaporation source provided in a deposition treatment chamber of a deposition device and an example of an evaporation material supply portion will be explained with reference to FIG. 7. In this embodiment mode, a structure will be shown, in which material liquid in which an evaporation material is dissolved or dispersed in a solvent is transferred and aerosolized by an atomizer, and the solvent in the aerosol is evaporated while vaporizing, in order to increase utilization efficiency and continuously perform evaporation to a large-sized substrate.

An evaporation material supply portion 76 has a structure in which material liquid in which an evaporation material is dissolved or dispersed in a solvent is dispersed in a carrier gas as a liquid particle (a particle having a grain size of approximately 1 to 1000 nm) and supplied to an evaporation source 52. An evaporation source 52 has a structure in which the solvent is vaporized from the liquid particle containing the evaporation material, and the evaporation material is further heated to be vaporized.

The evaporation material supply portion 76 includes a material liquid storage portion 114 for storing material liquid in which an evaporation material is dissolved or dispersed in a solvent; a material liquid supply means 116 including a pump for transferring the material liquid, a flow control valve, or the like; and a gas flow controller 110 for adjusting flow of a carrier gas. As a solvent, for example, tetrahydrofuran, chloroform, dimethylformamide, dimethylsulfoxide, or the like can be used. As a carrier gas, one or plurality of gasses selected from an inert gas such as helium, argon, krypton, or xenon; a nitrogen gas; and a hydrogen gas can be used.

The material liquid and a carrier gas are supplied to an aerosol formation portion 118 in the evaporation source 52 through a. material supply tube 60 and a gas supply tube 108, respectively. It is preferable that the aerosol formation portion 118 include an atomizer by which the material liquid and a carrier gas are mixed and sprayed at high speed. In addition, the mixture may be in a form of mist by using an ultrasonic transducer The aerosol sprayed from the aerosol formation portion 118 is heated in a cylinder cell 120 heated by a heater 102, the solvent is vaporized from the liquid particle, and the evaporation material is further heated to be vaporized. Then, the aerosol is emitted with the carrier gas from an opening at one end of the cylinder cell 120. The cylinder cell 120 is preferably formed from a ceramic such as alumina, boron nitride, or silicon nitride in order to suppress catalysis with an evaporation material containing an organic substance.

A temperature of the cylinder cell 120 is set to be a temperature by which an evaporation material in the aerosol can be evaporated or sublimated. In this case, the temperature may be set so as to increase from a connecting portion of the aerosol formation portion 118 toward an opening (an opening through which vapor is emitted) in the cylinder cell 120. A structure in which a collision cross-section area becomes large without disturbing a flow of aerosol is employed inside the cylinder cell 120. For example, a plurality of fins that is declined to be placed along the flow of aerosol may be provided inside the cylinder cell 120. In either case, a micro particle like aerosol has a large surface area; therefore a solvent can be vaporized at a lower temperature than boiling point in the air.

By applying the evaporation material supply portion of this embodiment mode to the evaporation sources in the deposition devices of Embodiment Modes 1 to 3, deposition can be continuously performed uniformly even in a case of a display panel having a large-sized screen. In addition, it is not necessary that the evaporation source is supplied with an evaporation material every time an evaporation material is used up; therefore, throughput can be improved.

### Embodiment Mode 6

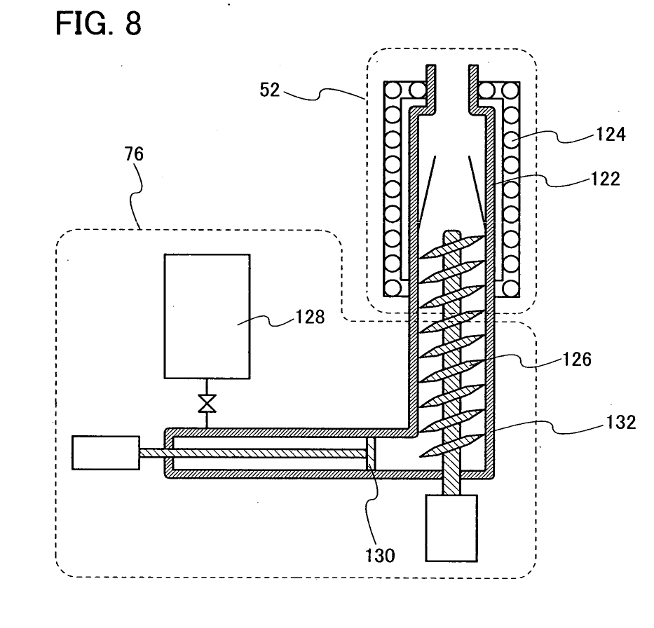

In this embodiment mode, an example of an evaporation source provided in a deposition treatment chamber of a deposition device and an example of an evaporation material supply portion will be explained with reference to FIG. 8. In this embodiment mode, an example will be explained, in which an evaporation material is continuously supplied by a mechanical means in order to increase utilization efficiency of the evaporation material and continuously perform evaporation to a large-sized substrate.

A cylinder cell 122 and a heater 124 constitute an evaporation source 52. Although a structure in which the cylinder cell 122 is heated by the heater 124 from outside of the cylinder cell 122 is shown in FIG. 8, the cylinder cell 122 and the heater 124 may be integrated. A material supply tube 132 is connected to the cylinder cell 122.

A temperature of the cylinder cell 122 which is heated by the heater 124 is set to be a temperature by which a powdery evaporation material to be supplied can be evaporated or sublimated. In this case, the temperature may be set so as to increase from a connecting portion of the material supply tube 132 toward an opening (an opening through which vapor is emitted) in the cylinder cell 122. By making the cylinder cell 122 have such a temperature gradient, an evaporation material can be efficiently consumed without clogging.

A transfer means 126 for continuously transferring an evaporation material by a mechanical structure is provided inside of the material supply tube 132. As the transfer means 126, a so-called screw in which a spiral plate is rolled around an axis, a piston which performs back-and-forth motion, or the like can be applied. An evaporation material is supplied from the other end of the material supply tube 132. In FIG. 8, a structure is employed, in which an evaporation material storage cell 128 for storing the evaporation material is provided, and an evaporation material supplied therefrom is supplied to the other end of the material supply tube 132 by a second transfer means 130.

Although a powdery evaporation material is preferably used, an evaporation material in paste form in which an evaporation material is dissolved or dispersed in a solvent, may also be used.

By applying the evaporation material supply portion of this embodiment mode to the evaporation sources in the deposition devices of Embodiment Modes 1 to 3, deposition can be continuously performed uniformly even in a case of a display panel having a large-sized screen. In addition, it is not necessary that the evaporation source is supplied with an evaporation material every time an evaporation material is used up; therefore, throughput can be improved. In particular, a structure of the evaporation source and the evaporation material supply portion relating to this embodiment mode is preferably applied to the deposition treatment chamber described in Embodiment Mode 2.

### Embodiment Mode 7

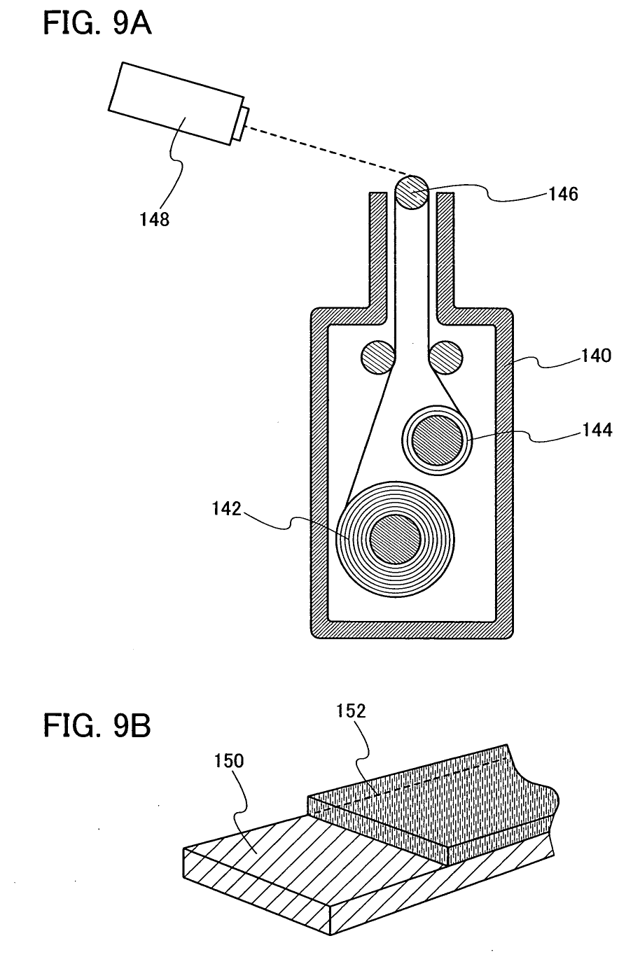

In this embodiment mode, an example of an evaporation source provided in a deposition treatment chamber of a deposition device and an example of an evaporation material supply portion will be explained with reference to FIGS. 9A and 9B. In this embodiment mode, an example will be explained, in which an evaporation material is continuously supplied by a mechanical means in order to increase utilization efficiency of the evaporation material and continuously perform evaporation to a large-sized substrate.

As shown in FIG. 9B, an evaporation material 152 which is attached on a flexible base film 150 is used. The evaporation material 152 in paste form, in which an evaporation material is dissolved or dispersed in a solvent, may be used, and the evaporation material 152 which is further dried may also be used. In addition, a powdery evaporation material may be pressed to be solidified. The long base film 150 to which the evaporation material 152 is attached is kept in an evaporation source 140 by being rolled around a reel 142, as shown in FIG. 9A. The other end of the long base film 150 is connected to a wind reel 144, and is sequentially discharged from the reel 142 through a touch roller 146.

A surface of the base film 150 to which the evaporation material 152 is attached is exposed in an opening which is an edge of an evaporation source 140. The exposed portion is irradiated with an energy beam, and the heated evaporation material 152 is evaporated or sublimated; accordingly, deposition is performed. As an energy beam supply source 148, a laser light source, an electron beam generator, or the like can be applied.

The evaporation material 152 is continuously supplied with the base film 150; therefore, deposition can be continuously performed. In addition, a crucible or the like which is an evaporation source is not required to be heated by a heater; therefore, energy consumption can be reduced.

By applying the evaporation material supply portion of this embodiment mode to the evaporation sources in the deposition devices of Embodiment Modes 1 to 3, deposition can be continuously performed uniformly even in a case of a display panel having a large-sized screen. In addition, it is not necessary that the evaporation source is supplied with an evaporation material every time an evaporation material is used up; therefore, throughput can be improved. In particular, a structure of an evaporation source and an evaporation material supply portion relating to this embodiment mode is preferably applied to the deposition treatment chamber described in Embodiment Mode 2.

### Embodiment Mode 8

In this embodiment mode, an example of an EL element manufactured by a deposition device provided with any one of structures of Embodiment Modes 1 to 7 will be explained. In this embodiment mode, an EL element having an EL layer between a pair of electrodes will be explained.

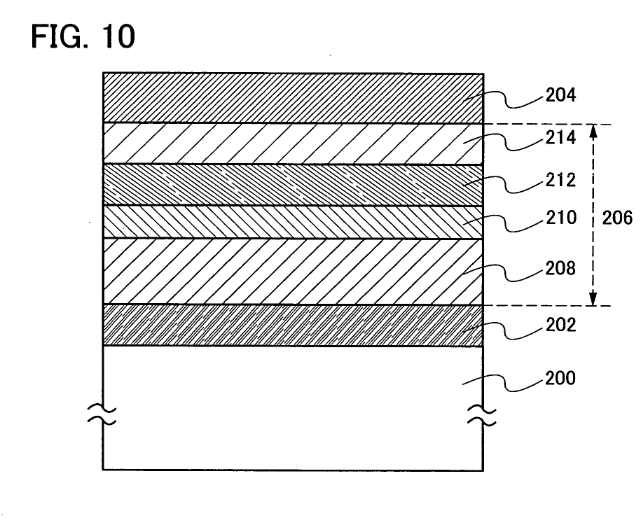

FIG. 10 shows a cross-sectional stacked structure of an EL element. In this EL element, an EL layer 206 is formed between a first electrode 202 and a second electrode 204. The EL layer 206 can be formed by a deposition device provided with the evaporation source of any one of Embodiment Modes 4 to 7. There is a case where a substrate 200 is used as a base in the EL element. As the substrate 200, glass, plastic, or the like can be used. It is to be noted that a material other than these may also be used as long as the EL element serves as a base in a manufacturing process. Hereinafter, an EL element is explained, in which holes are injected from the first electrode 202 (hereinafter, also referred to as an anode) and electrons are injected from the second electrode 204 (hereinafter, also referred to as a cathode), which results in light emission.

As the first electrode 202, various metals, alloys, electrically conductive compounds, and a mixture metal, a compound, and an alloy of these can be used. For example, indium tin oxide (ITO), indium tin oxide containing silicon, zinc oxide (ZnO), indium zinc oxide in which zinc oxide is mixed with indium oxide, or the like can be used. Besides, gold (Au), platinum (Pt), nickel (Ni), tungsten (W), chromium (Cr), molybdenum (Mo), iron (Fe), cobalt (Co), titanium (Ti), copper (Cu), palladium (Pd), aluminum (Al), aluminum-silicon (Al—Si), aluminum-titanium (Al—Ti), aluminum-silicon-copper (Al—Si—Cu), or nitride of a metal material can be used. In a case of using the first electrode 202 as an anode, in either case, the first electrode 202 is preferably formed using indium tin oxide which has a high work function (a work function of 4.0 eV or more).

The EL layer 206 includes a first layer 208, a second layer 210, a third layer 212, and a fourth layer 214 from the first electrode 202 side.

The first layer 208 is a layer having carrier injecting and transporting properties, and is preferably formed from a composite material containing metal oxide and an organic compound. As metal oxide, metal oxide that belongs to Groups 4 to 8 of the periodic table can be used. Specifically, vanadium oxide, niobium oxide, tantalum oxide, chromium oxide, molybdenum oxide, tungsten oxide, manganese oxide, and rhenium oxide are preferable because of a high electron accepting property. Above all, molybdenum oxide is preferable because of stability even in the air and easiness of treatment.

It is preferable that a combination of metal oxide and an organic compound be a combination in which the organic compound is easily oxidized by the metal oxide, that is a radical cation of the organic compound, which is in the metal oxide, is easily generated. For example, as an organic compound used for a composite material, an aromatic amine compound, a carbazole derivative, aromatic hydrocarbon, a metal complex, an organic metal complex, a high molecular compound (such as oligomer, dendrimer, or polymer) can be used. Accordingly, effects such as improvement in conductivity of the composite material and enhancement of a carrier injecting property (especially a hole injecting property) to an organic compound can be obtained, as compared with a organic compound alone. Moreover, an electric barrier with various metals can be eased and contact resistance can be reduced.

The second layer 210 is a layer formed from a substance having a high hole transporting property, for example, a compound of aromatic amines (namely, having a benzene ring-nitrogen bond) such as 4,4′-bis[N-(1-napthyl)-N-phenylamino]biphenyl (abbreviation: NPB), N,N′-bis(3-methylphenyl)-N,N ′-diphenyl-[1,1′-biphenyl]-4,4′-diamine (abbreviation: TPD), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA). The substances herein described are mainly substances having a hole mobility of 10⁻⁶ cm²/Vsec or more. It is to be noted that substances other than these may also be used as long as they are substances having a hole transporting property higher than an electron transporting property. Further, the second layer 210 may be formed of two or more stacked layers formed from the above-described substance as well as a single layer.

The third layer 212 contains a light-emitting material. As the light-emitting material, a substance having a high light-emitting property such as N,N′-dimethylquinacridone (abbreviation: DMQd) or 3-(2-benzothiazoyl)-7-diethylaminocoumarin (abbreviation: coumarin 6), and a substance, which has a high carrier transporting property and is not easily crystallized, such as tris(8-quinolinolato)aluminum (abbreviation: Alq) or 9,10-di(2-naphthyl)anthracene (abbreviation DNA) are preferably combined. In addition, Alq or DNA are substances having a high light-emitting property; therefore, a structure in which these substances are singularly used may also be used.

The fourth layer 214 can be formed from a metal complex having a quinoline skeleton or a benzoquinoline skeleton such as tris(8-quinolinolato)aluminum (abbreviation: Alq), tris(5-methyl-8-quinolinolato)aluminum (abbreviation as Almq₃), bis(10-hydroxybenzo[h]-quinolinato)beryllium (abbreviation as BeBq₂), or bis(2-methyl-8-quinolinolato)-4-phenylphenolato-aluminum (abbreviation: BAlq), or the like. Also, a metal complex having an oxazole based or thiazole based ligand such as bis[2-(2-hydroxyphenyl)-benzoxazolato]zinc (abbreviation as Zn(BOX)₂), or bis[2-(2-hydroxyphenyl)-benzothiazolato]zinc (abbreviation as Zn(BTZ)₂), or the like can be used. In addition to the metal oxide, 2-(4-biphenylyl)-5-(4-tert-buthylphenyl)-1,3,4-oxadiazole (abbreviation as PBD), 1,3-bis[5-(p-tert-buthylphenyl)-1,3,4-oxadiazole-2-yl]benzene (abbreviation as OXD-7), 3-(4-tert-buthylphenyl)-4-phenyl-5-(4-biphenylyl)-1,2,4-triazole (abbreviation as TAZ), 3-(4-tert-buthylphenyl)-4-(4-ethylpheyl)-5-(4-biphenylyl)-1,2,4-triazole (abbreviation as p-EtTAZ), bathophenanthroline (abbreviation as BPhen), bathocuproin (abbreviation as BCP), or the like can be used. The substances herein described are substances having electron mobility of 10⁻⁶ cm²/Vsec or more. It is to be noted that other substances may also be used as long as they have an electron transporting property higher than a hole transporting property.

As the second electrode 204, metal, alloy, or an electrically conductive compound having a low work function (a work function of 3.8 eV or less), and a mixture of these can be used. For example, an element that belongs to Group 1 or 2 of the periodic table, that is, alkali metal such as lithium (Li) or cesium (Cs); alkaline earth metal such as magnesium (Mg), calcium (Ca), or strontium (Sr); and alloy containing these metals (Mg: Ag, Al: Li) can be used. The second electrode 204 can be formed by combining a layer of a metal or metal oxide and the EL layer 206, and an electron injecting layer. As the electron injecting layer, a compound of alkali metal or alkaline earth metal such as lithium fluoride (LiF), cesium fluoride (CsF), or fluoride calcium (CaF₂) can be used. In addition, a layer in which alkali metal or alkaline earth metal is contained in a layer formed from a substance having an electron transporting property, for example, a layer in which magnesium (Mg) is contained in Alq, or the like can be used.

It is to be noted that the structure of the EL layer 206 is not limited to the structure shown in FIG. 10, and other structures may be used as long as light emission can be obtained by applying an electric field. In other words, a structure other than the one shown in FIG. 10 may also be used as long as the structure has a region, in which holes and electrons are recombined, provided in a site away from the first electrode 202 and the second electrode 204, so that quenching due to proximity of a light-emitting region and metal is suppressed.

From the viewpoint of a carrier transporting property, one or a plurality of kinds that are referred to as a hole injecting layer, a hole transporting layer, a light-emitting layer, an electron transporting layer, an electron injecting layer, or the like are included in the EL layer 206. Boundaries of each layer are not necessarily clear, and there is a case where part of materials forming each other's layers are mixed and the boundary is unclear. An organic material or an inorganic material can be used for each layer. As the organic material, any of high molecular, middle molecular, and low molecular materials can be used. Also, the electrode is preferable as long as it has a function of applying an electric field to the EL layer, and a conductive layer of a metal or metal oxide and a carrier transporting layer or a carrier injecting layer which is in contact with the conductive layer can also be used.

In the EL element having the structure as described above, a current flows in the EL layer 206 by applying voltage between the first electrode 202 and the second electrode 204: accordingly, light emission (luminescence) can be obtained. In FIG. 10, such a structure in which a light-emitting region is formed in the third layer 212 is employed. It is to be noted that an entire part of the third layer 212 does not necessarily serve as a light-emitting region, for example, a structure in which a light-emitting region is formed only at the second electrode 210 side or the fourth layer 214 side in the third layer 212 may also be employed.

If one of the first electrode 202 and the second electrode 204 is made to have a light-transmitting property and the other is made to have a light-reflecting property, light from the EL layer 206 can be emitted from the light-transmissive electrode side. In addition, if both of the first electrode 202 and the second electrode 204 are made to have a light-transmitting property, an EL element in which light from the EL layer 206 can be emitted from both of the electrodes can be obtained.

As explained in Embodiment Mode 1, such an EL element can be formed by a deposition device provided with a plurality of deposition treatment chambers shown in FIG. 1. For example, the substrate 200 over which an indium tin oxide film is formed as the first electrode 202 is put in a load chamber 14 to be evacuated.

Thereafter, the substrate 200 is introduced to a heat treatment chamber 18 by a transfer means 40. In the heat treatment chamber 18, the substrate 200 is heated to perform degassing treatment. Also, the substrate 200 may be transferred to a plasma treatment chamber 26, and a surface of the first electrode 202 may be processed by oxygen plasma treatment. These treatments in the heat treatment chamber 18 may be arbitrarily performed, and can be omitted.

The substrate is introduced to a deposition treatment chamber 20, and the first layer 208 is deposited over the first electrode 202. In order to deposit the first layer 208 formed from a composite material containing metal oxide and an organic compound, an evaporation source of metal oxide and an evaporation source of an organic compound are provided in the deposition treatment chamber 20. Co-evaporation is performed by using at least these two kinds of evaporation sources. The structure of any one of Embodiment Modes 4 to 7 can be applied to a structure of the evaporation. It is needless to say that the two kinds of evaporation sources do not necessarily have the same structure, and different structure may be combined. In a case of evaporating metal oxide by transferring a powder by an airflow as in Embodiment Mode 4, oxygen can be used as carrier gas. Oxygen is supplied in the deposition treatment chamber 20; accordingly, differences from a stoichimetric composition of metal oxide can be suppressed. In addition, as for an organic compound, a method of aerosolizing as in Embodiment Mode 5 can be applied. In either case, the first layer 208 is a layer having carrier injecting and transporting properties, which is formed so as to have resistivity of 5×10⁴ to 1×10⁶ Ωcm with a thickness of 30 to 300 nm.

Thereafter, the second layer 210 is deposited in the deposition treatment chamber 20. For example, NPB is deposited as a substance having a high hole transporting property for the second layer 210. It is to be noted that the second layer 210 may be transferred to other deposition treatment chambers to be deposited.

Over the substrate 200 transferred to a deposition treatment chamber 24, the third layer 212 is deposited. The third layer 212 contains a light-emitting material, and an evaporation material in accordance with an emission color is deposited. As for a structure of an evaporation source, the structure of any one of Embodiment Modes 4 to 7 can be applied. It is needless to say that the two kinds of evaporation sources do not necessarily have the same structure, and different structures may be combined. In a case where a plurality of layers each having a different light emission color is deposited in every EL element or one EL element, one layer is deposited, and then the substrate 200 may be transferred to deposition treatment chambers 28 and 30, and other layers are deposited. By using separate deposition treatment chambers, a light-emitting substance is not improperly mixed; accordingly, an element having high emission color purity can be manufactured.

Over the substrate 200 transferred to a deposition treatment chamber 32, the fourth layer 214 is deposited. A film of Alq or the like is deposited as an electron transporting layer for the fourth layer 214. Furthermore, the substrate 200 is transferred to a deposition treatment chamber 34, and the second electrode 204 is deposited.

The substrate 200 over which the EL layer 206 and the second electrode 204 are formed is transferred to a sealing treatment chamber 38 through an intermediate chamber 36. The sealing treatment chamber 38 is filled with an inert gas such as helium, argon, neon, or nitrogen, and under the atmosphere, a sealing plate is attached to a side of the substrate 200 where the EL layer 206 is formed; accordingly, sealing is performed. Under a sealed state, a space between the substrate 200 and the sealing plate may be filled with an inert gas or a resin material.

An EL element can be obtained as described above. According to this embodiment mode, deposition can be continuously performed uniformly even in a case of a display panel having a large-sized screen. In addition, it is not necessary that the evaporation source is supplied with an evaporation material every time an evaporation material is used up; therefore, throughput can be improved.

### Embodiment Mode 9

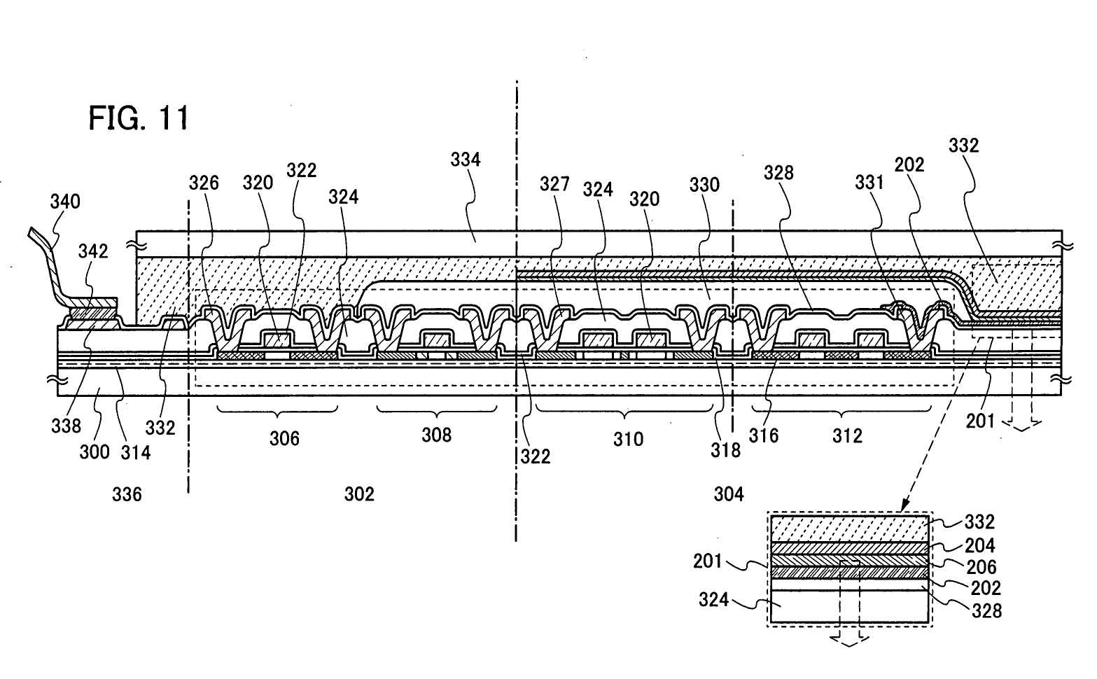

In this embodiment mode, an example of a light-emitting device manufactured by the deposition devices described in Embodiment Modes 1 to 7 will be explained with reference to FIG. 11. It is to be noted that the light-emitting device includes a device for displaying a character, a figure, a symbol, a sign, a still image, a moving image, or the like by setting a plurality of display units which are also referred to as pixels. There are various arrangements of pixels such as pixels arranged in a matrix form or in a segment form. Besides, the light-emitting device includes a device in general for displaying information by changing contrasting, color tone, or the like. Moreover, the light-emitting device includes a device in general which is used as a light source or lighting.

FIG. 11 shows a light-emitting device in which a driver circuit 302 and a display portion 304 that are formed over an element substrate 300 are sealed by a sealing substrate 334.

A P-channel first transistor 306 and an N-channel second transistor 308 are shown as representative examples of transistors used for the driver circuit 302. The first transistor 306 is formed by including a semiconductor layer 316, an insulating layer 318 serving as a gate insulating layer, and a gate electrode 320. In addition, an insulating layer 314 as a blocking layer against a contaminant is formed below the semiconductor layer 316. The semiconductor layer 316 can be formed using single crystalline silicon, polycrystalline silicon, or amorphous silicon.

The second transistor 308 is the same as the first transistor 306. The second transistor 308 is formed so as to serve as a transistor by arbitrarily providing impurity regions such as a source and a drain formed in the semiconductor layer 316. A single drain structure in which a channel formation region is provided between a pair of source and drain, an LDD structure in which a lightly doped (LDD) drain is provided between the channel formation region and the drain, a gate overlapped drain structure in which LDD is overlapped with a gate electrode, or the like can be arbitrarily selected to be used for the transistor. By these transistors, a shift resistor circuit, a latch circuit, a level shifter circuit, a switch circuit, or the like is formed to constitute the driver circuit 302.

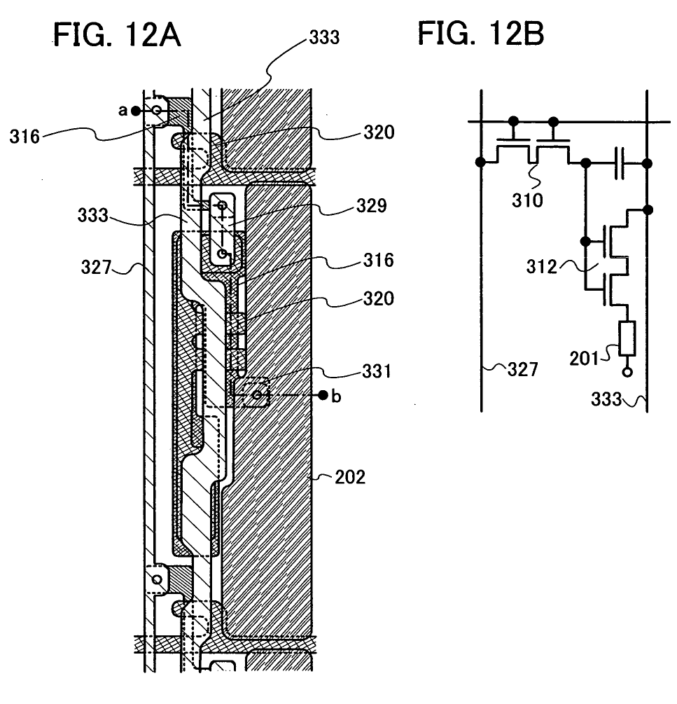

An N-channel third transistor 310 and a P-channel fourth transistor 312 included in one pixel are shown as representative examples of transistors used for the display portion 304. FIG. 12A shows a top view of this pixel, and a cross-sectional view taken along a line a-b is shown in FIG. 11. In addition, FIG. 12B shows an equivalent circuit of the pixel. In the third transistor 310 and the fourth transistor 312, a plurality of gate electrodes is placed between a pair of source and drain, and a multi-gate structure is shown, in which a plurality of channel formation regions is connected in series.

A passivation layer 322 and an interlayer insulating layer 324 are formed over the gate electrode 320, and a wiring 326 is formed thereover. In the display portion 304, a wiring 327 to which a pixel signal is supplied, a wiring 333 as a power supply line, and a wiring 329 which connects the third transistor 310 and the fourth transistor 312 are formed. A partition wall layer 330 is formed over the wiring 329, having an insulating layer 328 therebetween. An EL element 201 is placed over the interlayer insulating layer 324. A first electrode 202 extends over the interlayer insulating layer 324 (or the insulating layer 328) to be connected to a wiring 331 of the fourth transistor 312. The partition wall layer 330 covers a peripheral end of the first electrode 202, and an opening is formed. The EL element includes the first electrode 202, an EL layer 206, and a second electrode 204, and the element described in Embodiment Mode 8 can be applied for the detail thereof. As shown in FIG. 11, in a case where light emission from the EL layer 206 is emitted to the first electrode 202 side, the first electrode 202 is formed of a transparent conductive film and the second electrode is formed of a metal electrode. A sealing material 332 is interposed between the element substrate 300 and the sealing substrate 334.

In FIG. 11, a structure is shown, in which the insulating layer 328 is provided between the first electrode 202 and the interlayer insulating layer 324 of the EL element. This insulating layer 328 effectively serves in order to prevent progressive defects of an EL element (time degradation and a defect such that non-emission region is developed) when a wiring layer is formed over the interlayer insulating layer 324 by etching and etching residue remains. Therefore, the insulating layer 328 can be omitted.

Although a top gate transistor structure in which the gate electrode 320 is formed after the semiconductor layer 316 is shown in FIG. 11, a bottom gate structure in which the semiconductor layer is formed after the gate electrode may also be employed. In particular, the latter is preferable in a case of using amorphous silicon.

A terminal 338 is provided at an end portion 336 of the element substrate 300, and is electrically connected to a wiring substrate 340 which is connected to an external circuit. A conductive adhesive 342 is provided in a connecting portion.

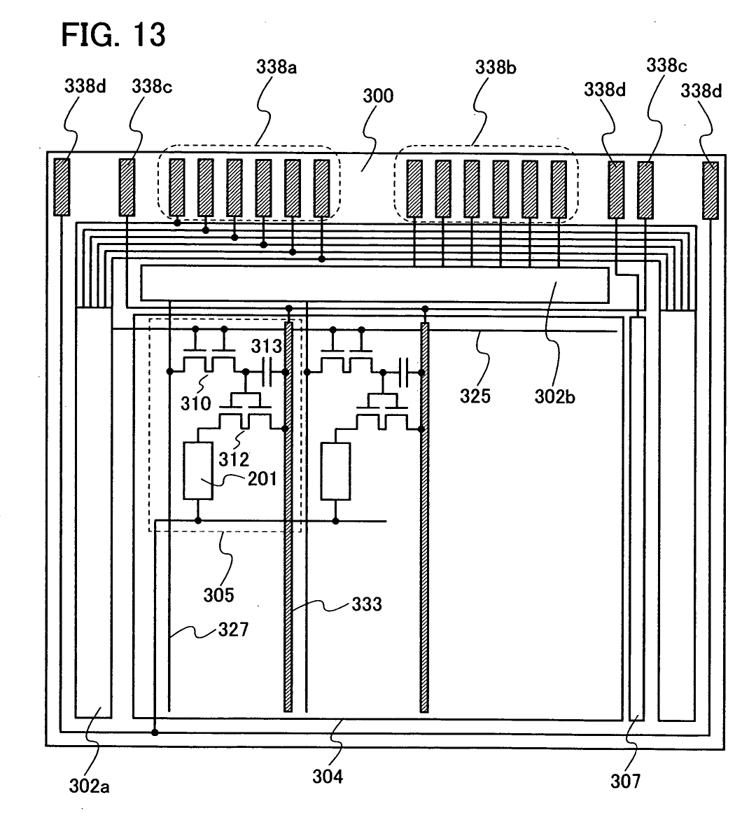

FIG. 13 shows a structure of the element substrate 300. A display portion 304 in which a plurality of pixels 305 is arranged is formed over the element substrate 300. As driver circuits, a scanning line driver circuit 302a and a signal line driver circuit 302b are formed. The display portion 304 includes a wiring 325 extending from the scanning line driver circuit 302a, a wiring 327 extending from the signal line driver circuit 302b, and a wiring 333 as a power supply line. In addition, a monitor circuit 307 for correcting luminance changes of an EL element 201 included in the pixel 305 may also be provided. The EL element 201 and an EL element included in the monitor circuit 307 have the same structure.

In a peripheral portion of the element substrate 300 has a terminal 338a which inputs a signal to the scanning line driver circuit 302a from an external circuit, a terminal 338b which inputs a signal to the signal line driver circuit 302b from the external circuit, and a terminal 338c which inputs a signal to the monitor circuit 307. The pixel 305 includes the third transistor 310 connected to the wiring 327 to which a pixel signal is supplied and the fourth transistor 312 inserted in series between the wiring 333 to which power is supplied and the EL element 201 to be connected. A gate of the third transistor 310 is connected to the wiring 325, and when being selected by a scanning signal, a signal of the wiring 327 to which a pixel signal is supplied is inputted to the pixel 305. An inputted signal is given to a gate of the fourth transistor 312, and storage capacitor portion 313 is charged. The wiring 333 and the EL element 201 are in a conduction state according to this signal, and the EL element 201 emits light.

Electric power is required to be supplied from an external circuit so that the EL element 201 provided in the pixel 305 emits light. The wiring 333 to which power is supplied is connected to the external circuit at the terminal 338c. Since resistance loss occurs in the wiring 333 due to the length of a wiring to be led, it is preferable to provide the terminals 338c at a plurality of positions in the periphery of the element substrate 300. The terminals 338c are provided at both end portions of the element substrate 300 so that luminance variations in the area of the display portion 304 do not become notable. That is, it is prevented that one side of the screen becomes bright while the other side thereof becomes dark. In addition, in the EL element 201 having a pair of electrodes, an electrode on the opposite side to the electrode connected to the wiring 333 to which power is supplied is formed as a common electrode shared by a plurality of pixels 305. In order to reduce the resistance loss of this electrode, a plurality of terminals 338d are provided.

In such a light-emitting device, as explained in Embodiment Mode 1, an EL element can be formed by the deposition device provided with a plurality of deposition treatment chambers shown in FIG. 1. For example, the element substrate 300 over which the driver circuit 302, each transistor of the display portion 304, the first electrode 202 connected to the fourth transistor 312, and the partition wall layer 330 are formed is transferred to a load chamber 14 so that the EL layer 206 is deposited. Embodiment Mode 8 can be referred to for the process.

According to this embodiment mode, deposition can be continuously performed with in-plane uniformity of an evaporation film, even in a case of a large-sized glass substrate having a side of longer than 1000 mm. In addition, it is not necessary that the evaporation source is supplied with an evaporation material every time an evaporation material is used up; therefore, throughput can be improved.

### Embodiment Mode 10

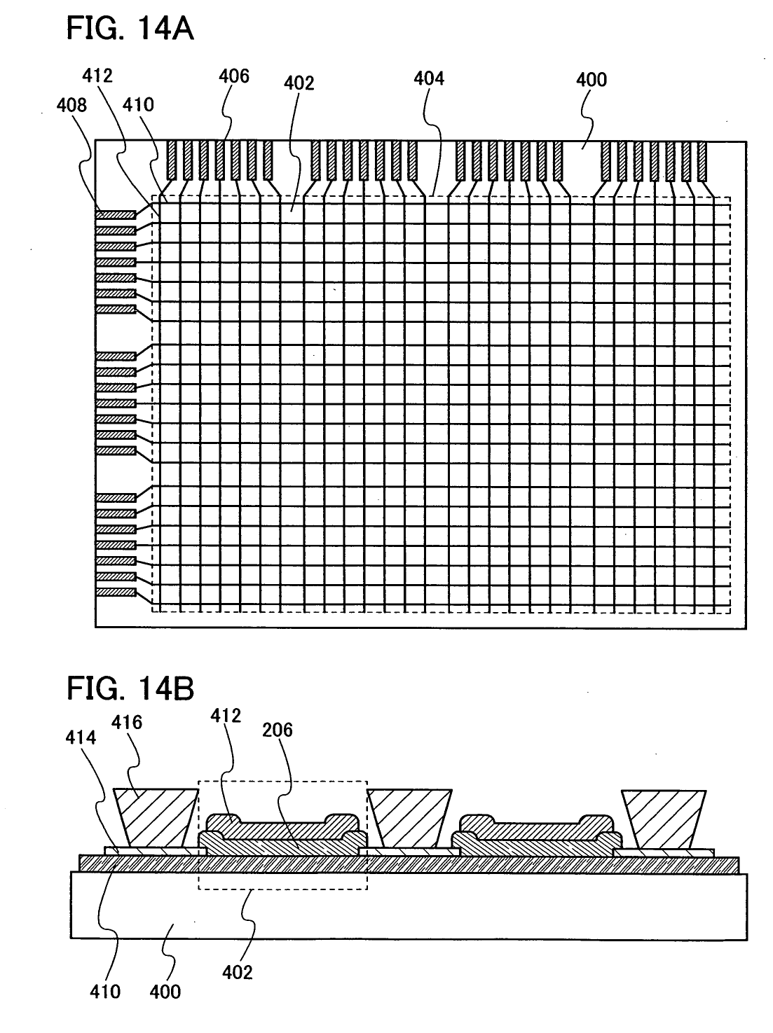

In this embodiment mode, an example of a light-emitting device which can be manufactured by the deposition device described in Embodiment Modes 1 to 7 will be explained with reference to FIGS. 14A and 14B.

FIG. 14A shows a top view of a light-emitting device, which shows a display portion 404 formed by arranging pixels 402 over a substrate 400. In addition, FIG. 14B shows a cross-sectional view of a structure of the pixel 402. Both drawings are referred to for the explanation below.

Over the substrate 400, wirings extending in one direction and wirings extending in another direction are formed so as to be intersected with each other. Here, one direction is referred to as an X direction and the other direction is referred to as a Y direction for convenience.

A wiring 410 extending in the X direction from a scanning line input terminal and a wiring 412 extending in the Y direction from a signal line input terminal are provided, and an EL layer 206 is formed at a portion where the both wirings are overlapped. At this time, the EL layer 206 may be formed in a stripe form in the same direction as the wiring 412 extending in the Y direction. A partition wall 416 is formed in a stripe form in the same direction as such an EL layer 206 and the wiring 412 extending in the Y direction. The partition wall 416 has a function of separating a set of the EL layer 206 and the wiring 412 extending in a striped shape from an adjacent set of the EL layer 206 and the wiring 412. The partition wall may have an inverse tapered cross-sectional shape as shown in FIG. 14B. In addition, an insulating layer 414 is provided between the partition wall 416 and the wiring 410 extending in the X direction so that the wiring 410 extending in the X direction and the wiring 412 extending in the Y direction are not in contact with each other.

In such a light-emitting device, as explained in Embodiment Mode 1, the EL layer 206 can be formed by the deposition device provided with a plurality of deposition treatment chambers shown in FIG. 1. For example, the substrate 400, over which the wiring 410 extending in the X direction in a stripe form, the insulating layer 414, and the partition wall 416 are formed, is transferred to a load chamber 14, and the EL layer 206 is deposited. Embodiment Mode 8 can be referred to for the process. In this case, an EL layer which is similar to the one in Embodiment Mode 8 can be applied for the EL layer 206. In addition, in a case of forming pixels each having a different light emission color such as red (R), green (G), and blue (B) in the display portion 404, the EL layer 206 may be made to have a different structure by using a shadow mask in evaporating. At this time, the partition wall 416 serves as a spacer so that the shadow mask is not directly in contact with the wiring 410 or the like.

According to this embodiment mode, deposition can be continuously performed with in-plane uniformity of an evaporation film, even in a case of a large-sized glass substrate having a side of longer than 1000 mm. In addition, it is not necessary that the evaporation source is supplied with an evaporation material every time an evaporation material is used up; therefore, throughput can be improved.

### Embodiment Mode 11

In this embodiment mode, an example of a light-emitting device which can be manufactured by the deposition devices described in Embodiment Modes 1 to 7 will be explained with reference to drawings. In particular, in this embodiment mode, a light-emitting device of which the manufacturing process includes a step of forming a predetermined pattern without using a photomask at least as part in a manufacturing process of an element substrate including a transistor will be explained with reference to drawings.

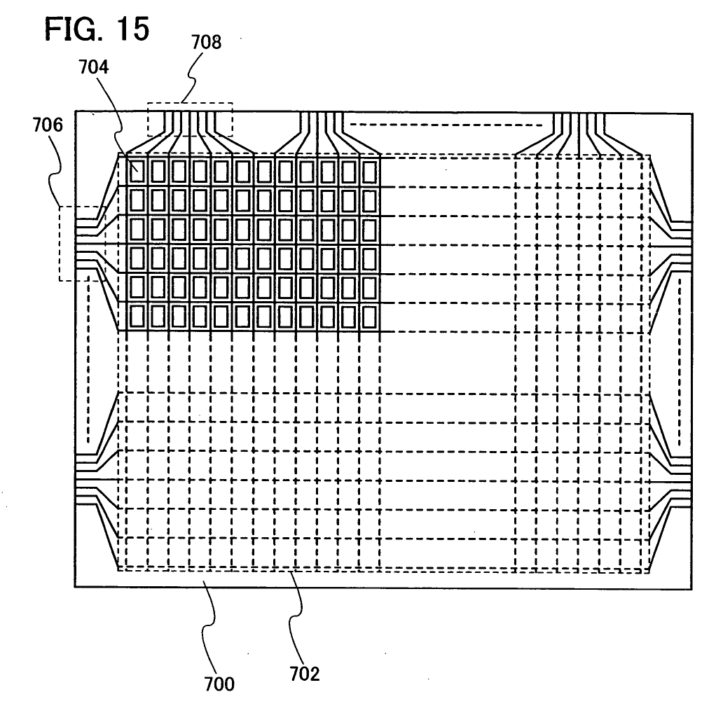

FIG. 15 shows a top view of a structure of a light-emitting device relating to this embodiment mode, in which a pixel portion 702 in which pixels 704 are arranged in a matrix form, a scanning line input terminal 706, and a signal line input terminal 708 are formed over a substrate 700. The number of pixels may be determined in accordance with various rules. In a case of XGA, the number of pixels may be 1024×768×3 (RGB), in a case of UXGA, the number of pixels may be 1600×1200×3 (RGB), and in a case of the use for a full spec high vision display, the number of pixels may be 1920×1080×3 (RGB).

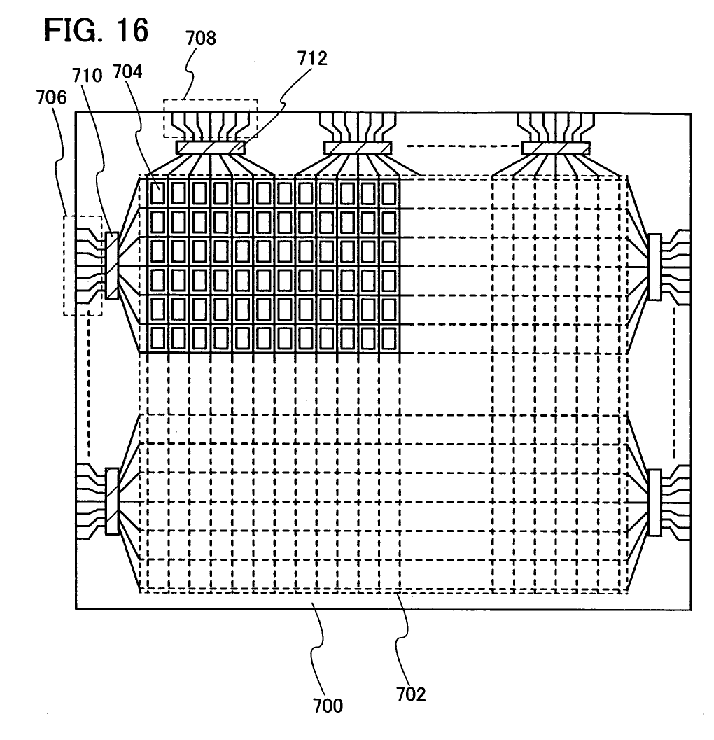

FIG. 15 shows a structure of a light-emitting device for controlling a signal inputted to a scanning line and a signal line by an external driver circuit. In addition, a driver IC may be mounted on the substrate 700 by COG (chip on glass) as shown in FIG. 16. FIG. 16 shows a mode in which a scanning line driver IC 710 and a signal line driver IC 712 are mounted on the substrate 700. The scanning line driver IC 710 is provided between the scanning line input terminal 706 and the pixel portion 702.

A scanning line extending from the input terminal 706 and a signal line extending from the input terminal 708 are intersected, and accordingly, pixels 704 are arranged in a matrix form. Each of the pixels 704 is provided with a transistor (hereinafter, also referred to as a “switching transistor” or a “switching TFT”) for controlling a connection state of the signal line and a driving transistor and a transistor (hereinafter, also referred to as a “driving transistor” or a “driving TFT”) for controlling a current flowing to an EL element, and the driving transistor is connected to the EL element in series.

The transistor is typically a field effect transistor, which includes a semiconductor layer, a gate insulating layer, and a gate electrode as its main component. A wiring connected to source and drain regions formed in the semiconductor layer is accompanied by it. Although a top gate structure in which a semiconductor layer, a gate insulating layer, and a gate electrode are provided from the substrate side, and a bottom gate structure in which a gate electrode, a gate insulating layer, and a semiconductor layer are provided from the substrate side are typically known, any structure may be used in the present invention. As a material for forming the semiconductor layer, an amorphous semiconductor formed by a vapor growth method or a sputtering method using a semiconductor material gas typified by silane or germane; a polycrystalline semiconductor in which the amorphous semiconductor is crystallized by using light energy or thermal energy; a semiamorphous semiconductor; or the like can be used.

Next, a step in which such a light-emitting device is realized with a channel protection transistor will be explained.

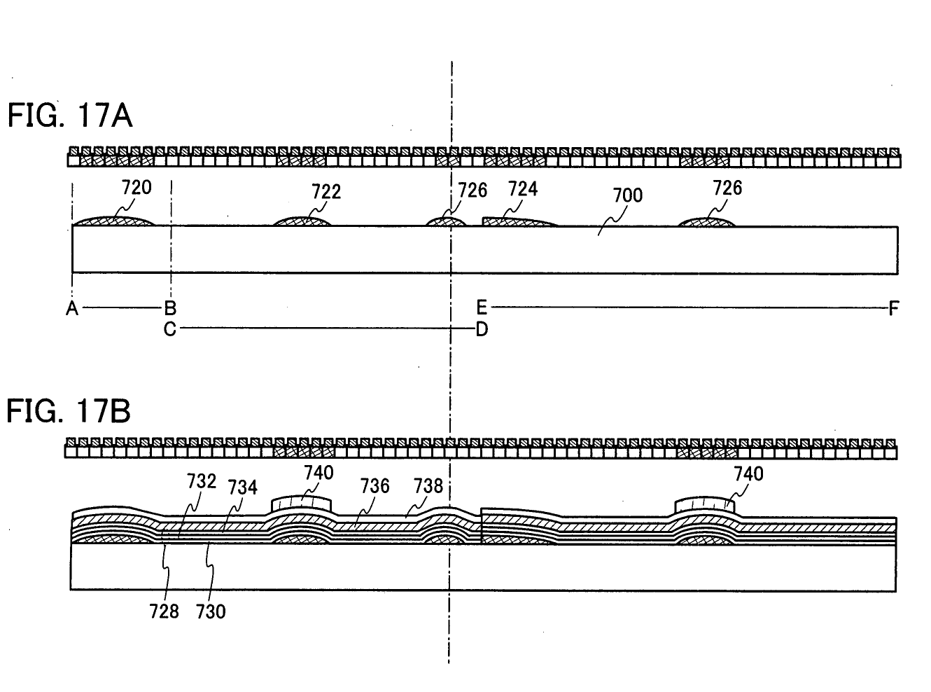

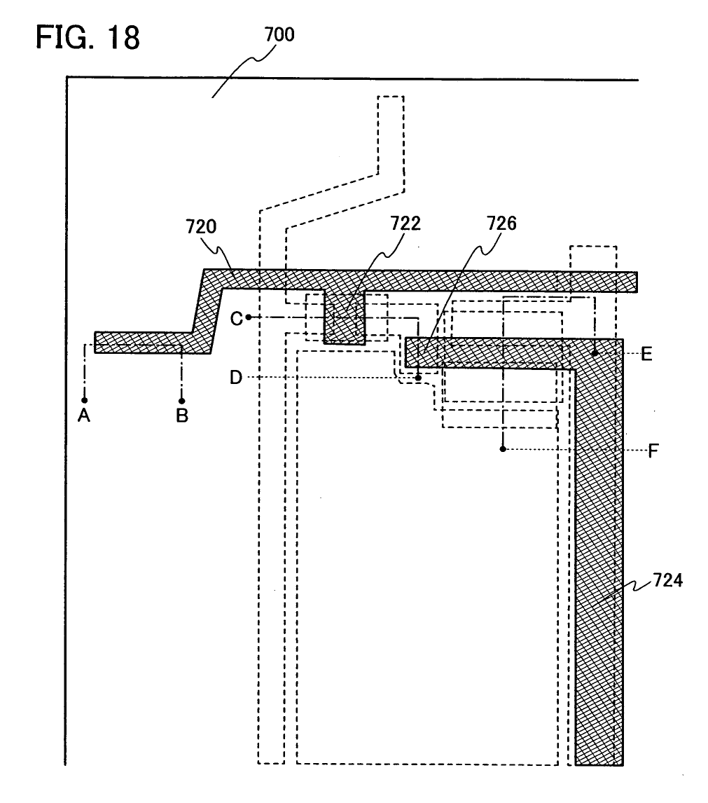

FIG. 17A shows a step in which a gate electrode, a gate wiring connected to the gate electrode, and a capacitor wiring are formed over a substrate 700 by a droplet discharging method. It is to be noted that FIG. 17A shows a vertical cross-sectional structure, and FIG. 18 shows a plane structure taken along lines A-B, C-D, and E-F.

The substrate 700 can be formed using a plastic substrate or the like having resistance to a processing temperature of this manufacturing process, in addition to a non-alkali glass substrate manufactured by a fusion method or floating method, such as barium borosilicate glass, alumino borosilicate glass, or aluminosilicate glass. Moreover, a substrate, in which an insulating layer is provided over a surface of a metal substrate, such as stainless steel alloy, may also be used.

A gate wiring 720, a gate electrode 722, a capacitor electrode 724, and a gate electrode 726 are formed over the substrate 700 by using a composition containing a conductive material by a printing method. As a conductive material forming these layers, a composite containing a metal particle as its main component, such as Ag (silver), Au (gold), Cu (copper), W (tungsten), Al (aluminum) may be used. In particular, resistance of the gate wiring is preferably reduced; therefore, the gate wiring is preferably formed using a composition in which any of gold, silver and copper is dissolved or dispersed in a solvent, in consideration of a specific resistance value. More preferably, silver or copper having low resistance is used. The gate electrode is required to be minutely formed; therefore, nano paste containing a particle having an average grain diameter of 5 to 10 nm is preferably used. The solvent corresponds to esters such as butyl acetate, alcohols such as isopropyl alcohol, an organic solvent such as acetone, and the like. The surface tension and viscosity are arbitrarily adjusted by adjusting concentration of a solution or adding a surface active agent or the like.

A printing method applied in this embodiment mode includes a screen printing method, a droplet discharging method (also referred to as an ink jetting method) discharging a droplet microdot, a dispenser method continuously supplying a small amount of droplet discharge while drawing a pattern, and the like. For example, a diameter of a nozzle used for a droplet discharging method is preferably set to be 0.02 to 100 μm (more preferably, 30 μm or less), and the amount of discharge of a composite discharged from the nozzle is preferably set to be 0.001 to 100 pl (more preferably, 10 pl or less). Although the droplet discharging method has two methods that are an on-demand type and a continuous type, both methods may be used. Furthermore, a nozzle used for a droplet discharging method has a piezoelectric method utilizing a property in which a piezoelectric substance transforms by voltage application and a method by which a composition is boiled by a heater provided in the nozzle to be discharged, and both methods may be used. It is preferable that a distance between an object to be processed and a discharging opening of the nozzle be as short as possible in order to drop a droplet on a desired place. The distance is preferably set to be approximately 0.1 to 3 mm (more preferably 1 mm or less). One of the nozzle and the object to be processed moves while keeping the relative distance between the nozzle and the object to be processed to draw a desired pattern. Also, plasma treatment may be performed to a surface of the object to be processed before discharging the composition. This is because the surface of the object to be processed becomes hydrophilic or lyphobic by plasma treatment. For example, the surface of the object to be processed becomes hydrophilic to pure water and lyphobic to a paste in which alcohol is used as a solvent.

A step of discharging the composition may be performed under reduced pressure because the solvent of the composition is volatilized while the composition is discharged and reaches the object to be processed and subsequent steps of drying and baking can be omitted or shortened. In addition, by positively using a gas in which 10 to 30% of oxygen in a partial pressure ratio is mixed in a baking step of a composition containing a conductive material, resistivity of a conductive film forming a gate electrode can be reduced, and the conductive film can be thinned and planarized.

After the composition is discharged, one or both of drying step and baking step is/are performed under normal pressure or reduced pressure by laser light irradiation, rapid thermal annealing, heating using a heating furnace, or the like. Although both of drying and baking are heat treatment steps, drying is performed at 100° C. for 3 minutes and baking is performed at 200 to 350° C. for 15 to 120 minutes, for example. A substrate may be heated in order to favorably perform drying and baking. Although a temperature at the time depends on a material of the substrate or the like, the temperature is set to be 100 to 800° C. (preferably, 200 to 350° C.). Through this step, fusion and welding are accelerated by hardening and shrinking of a peripheral resin, while the solvent in the composition is volatilized or the dispersant is chemically removed. The step is performed under an oxygen atmosphere, a nitrogen atmosphere, or the air. However, it is preferable that an oxygen atmosphere in which a solvent in which a metal element is dissolved or dispersed is easily removed be used. A continuous wave or pulsed gas laser, or solid-state laser may be used for laser irradiation. Rapid thermal annealing (RTA) is performed as follows: under an inert gas atmosphere, an infrared lamp, a halogen lamp, or the like is used, a temperature is rapidly increased, and heat is instantaneously applied within several micro seconds to several minutes. Since this treatment is instantaneously performed, only an outermost thin film can be substantially heated.

In this step, heat treatment may be performed by laser irradiation or rapid thermal annealing in order to smooth surfaces of the formed gate wiring 720, gate electrode 722, capacitor electrode 724, and gate electrode 726, and especially in order to increase the fluidity of a superficial layer.

Nano paste has a conductive particle having a grain diameter of 5 to 10 nm dispersed or dissolved in an organic solvent, and dispersant and a thermal curing resin which is referred to as a binder are included. A binder has a function of preventing crack or uneven baking during baking. By a drying step or a baking step, evaporation of the organic solvent, dispersion removal of dispersant, and hardening shrinking by the binder concurrently proceed; accordingly, nano particles are fused and/or welded to each other to be cured. In this case, the nano particles grow to be several tens nm to several hundreds nm. Adjacent growing particles are fused and/or welded to each other to be linked to form a metal hormogone. On the other hand, most of remaining an organic constituent (about 80 to 90%) are pushed out of the metal hormogone; consequently, a conductive film containing the metal hormogone and organic constituent which covers an outer side thereof remain. The remaining organic constituent can be removed in baking a nano paste under an atmosphere containing nitrogen and oxygen by reaction of oxygen contained in the air and carbon, hydrogen or the like contained in a film formed of the organic constituent. In addition, in a case where oxygen is not contained in a baking atmosphere, the organic constituent can be removed by separately performing oxygen plasma treatment or the like. As described above, the remaining organic constituent is removed by baking the nano paste under an atmosphere containing nitrogen and oxygen or performing oxygen plasma treatment after drying; therefore, smoothing, thinning, and low resistivity of a conductive film containing the remaining metal hormogone can be attempted. It is to be noted that since a solvent in a composition is volatilized by discharging the composition containing a conductive material under reduced pressure, time of subsequent heat treatment (drying or baking) can be shortened.

In FIG. 17B, a gate insulating layer 728 is formed of a single layer or a stacked layer by using a plasma CVD method or a sputtering method. As a preferable mode, three stacked layers of a first insulator layer 730 formed from silicon nitride, a second insulator layer 732 formed from silicon oxide, and a third insulator layer 734 formed from silicon nitride are formed as the gate insulating layer. It is to be noted that a rare gas element such as argon is contained in a reactive gas to be mixed into an insulating film which is formed, in order to form a dense insulating film with little gate leak current at a low deposition temperature. By forming the first insulator layer 730 which is in contact with the gate wiring 720, the gate electrode 722, the capacitor electrode 724, and the gate electrode 726 from silicon nitride or silicon nitride oxide, deterioration due to oxidation can be prevented.

Subsequently, a semiconductor layer 736 is formed. The semiconductor layer 736 is formed by a semiconductor which is formed by a vapor growth method or a sputtering method using a semiconductor material gas, typified by silane or germane. Typically, amorphous silicon or hydrogenated amorphous silicon can be used.

An insulator layer 738 is formed over the semiconductor layer 736 by a plasma CVD method or a sputtering method. This insulator layer 738 is left over the semiconductor layer 736 to be opposite to the gate electrode so as to be a channel protection layer, as shown in a subsequent step. It is preferable that the insulator layer 738 be formed of a dense film in order to prevent outside impurity such as metal or an organic substance and keep an interface between the insulator layer 738 and the semiconductor layer 736 clean. This insulator layer 738 is desirably formed at a low temperature. For example, a silicon nitride film which is formed by a plasma CVD method using silane or disilane diluted with a rare gas such as argon by 100 to 500 times can be formed of a dense film even at a deposition temperature of 100° C. or less, which is preferable.

In FIG. 17B, a mask 740 is formed at a position which is over the insulator layer 738 and is opposite to the gate electrode 722 and the gate electrode 726, by selectively discharging a composition. The mask 740 is formed using a resin material such as an epoxy resin, an acrylic resin, a phenol resin, a novolac resin, a melamine resin, or urethane resin. In addition, the mask 740 is formed by a droplet discharging method using an organic material such as benzocyclobutene, parylene, or polyimide having a light-transmitting property; a compound material made by polymerization of a siloxane-based polymer or the like; a composition material containing a water-soluble homopolymer and a water-soluble copolymer; or the like. Alternatively, a commercial resist material containing a photosensitizer may be used. For example, a typical positive type resist such as a novolac resin or a naphthoquinone diazide compound that is a photosensitizer, or a negative type resist such as a base resin, diphenylsilanediol, or an acid generator may be used. In using whichever material, the surface tension and the viscosity are appropriately controlled by performing dilution by a solvent or adding a surfactant or the like. Then, the insulator layer 738 is etched by using the mask 740 to form an insulator layer 742 serving as a channel protection layer.

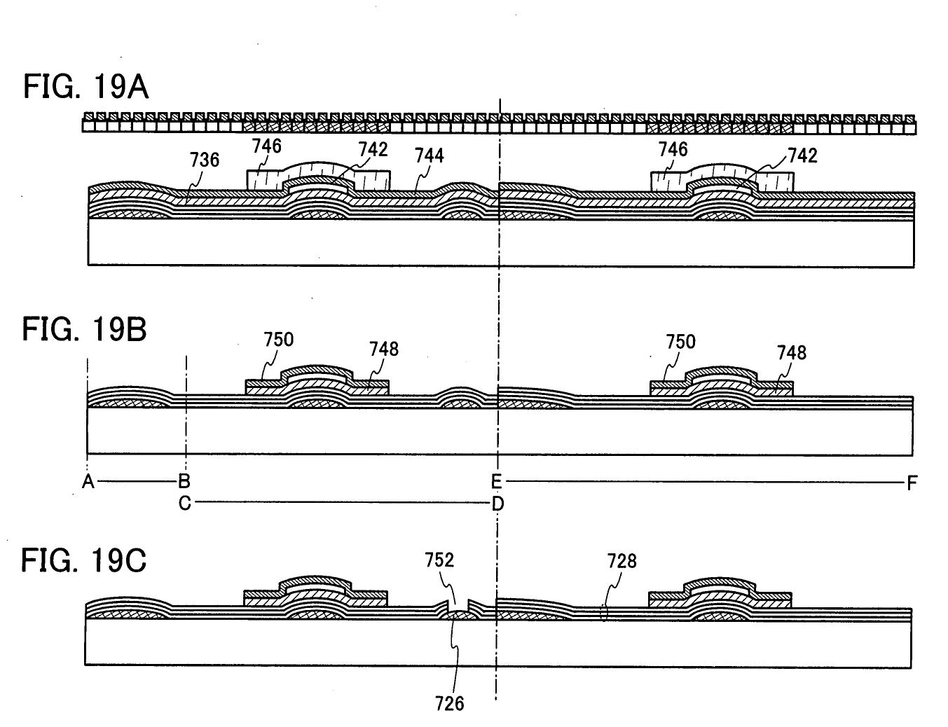

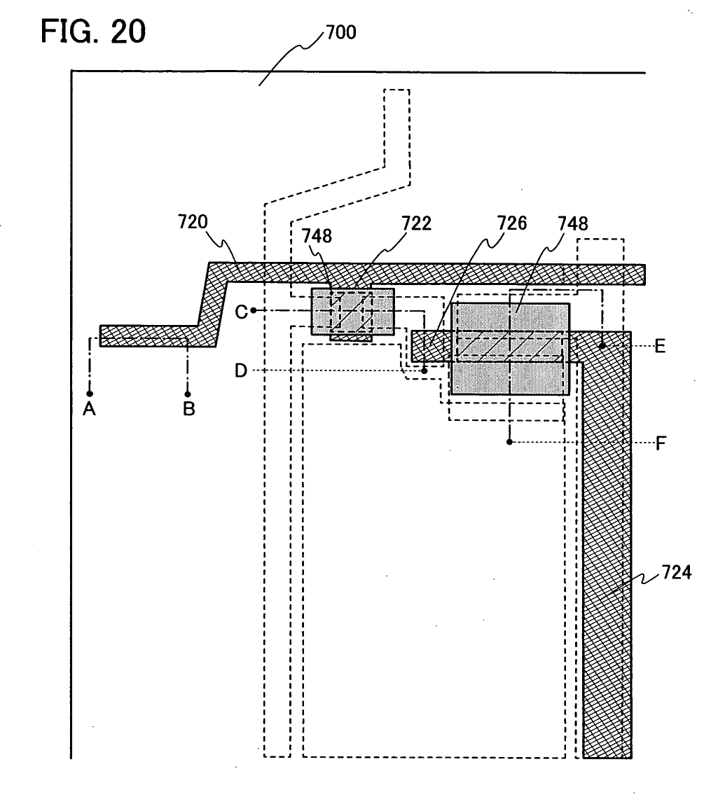

In FIG. 19A, the mask 740 is removed to form an n-type semiconductor layer 744 over the semiconductor layer 736 and the insulator layer 742. Furthermore, a mask 746 is formed over the n-type semiconductor layer 744 by a droplet discharging method. In FIG. 19B, the n-type semiconductor layer 744 and the semiconductor layer 736 are etched using the mask 746 to form a semiconductor layer 748 and an n-type semiconductor layer 750. Further, a plane structure taken along lines A-B, C-D, and E-F in a longitudinal plane structure of FIG. 19B is shown in-FIG 20.

Subsequently, a through hole 752 is formed in the gate insulating layer 728 by an etching process as shown in FIG. 19C to expose part of the gate electrode 726 which is placed at the lower layer. The etching process may be performed using the same mask as the above-described mask by a droplet discharging method. Either plasma etching or wet etching may be employed for the etching process. Plasma etching is suitable for processing a large-sized substrate. As an etching gas, a fluorine-based gas or a chlorine-based gas such as CF₄, NF₃, C1₂ or BCl₃ is used, to which He, Ar or the like may be appropriately added. Alternatively, electric discharge machining may be performed locally when the etching process is performed using atmospheric pressure discharge, in which case a mask layer is not required to be formed over the entire surface of the substrate.

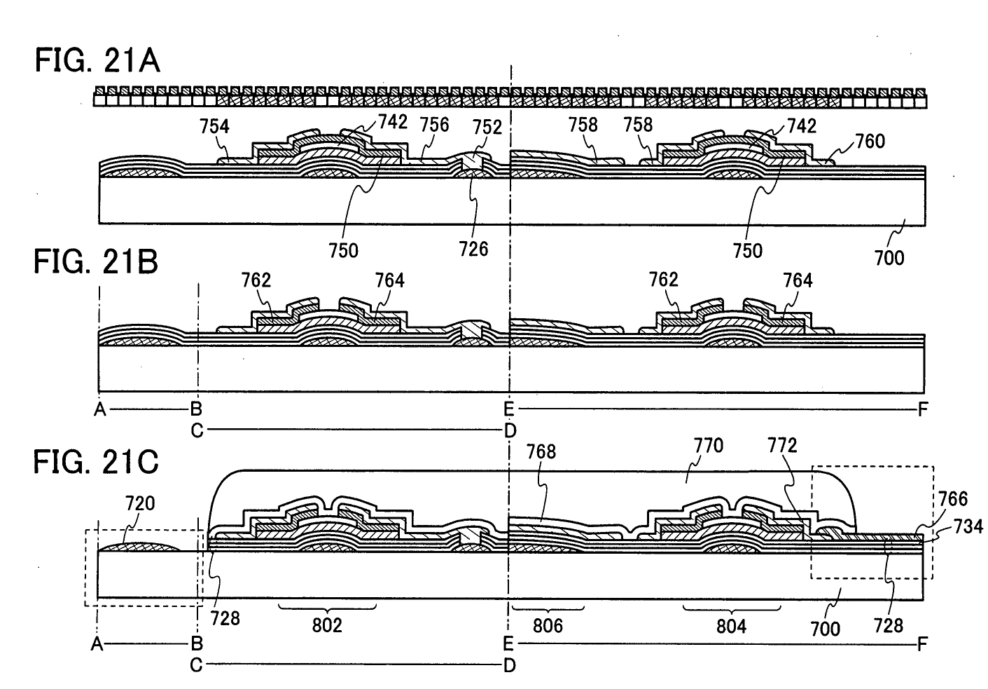

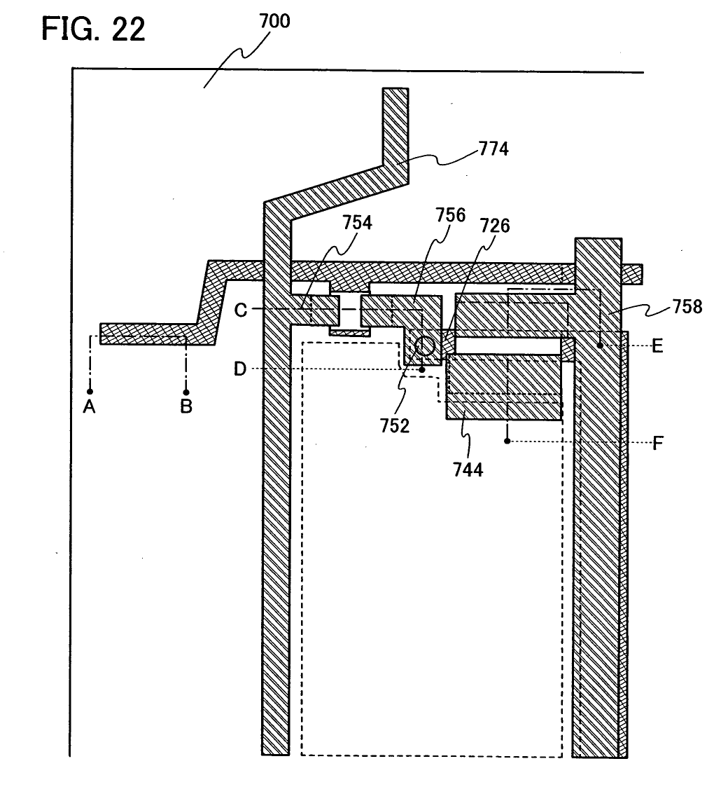

In FIG. 21A, a composition containing a conductive material is selectively discharged to form wirings 754, 756, 758, and 760 that are connected to a source and a drain, by a droplet discharging method. A plane structure taken along lines A-B and C-D in a longitudinal structure of FIG. 21A is shown in FIG. 22. As shown in FIG. 22, a wiring 774 extending from one end of a substrate 700 is formed concurrently. The wiring 774 is placed so as to be electrically connected to the wiring 754. In addition, as shown in FIG. 21A, in the through hole 752 formed in the gate insulating layer 728, the wiring 756 and the gate electrode 726 are electrically connected. As a conductive material for forming the wiring, a composition containing a metal particle such as Ag (silver), Au (gold), Cu (copper), W (tungsten), or Al (aluminum) as its main component can be used. Also, indium tin oxide (hereinafter, also referred to as “ITO”) having a light-transmitting property, indium tin oxide containing silicon oxide, organic indium, organotin, zinc oxide, titanium nitride, or the like may be combined.

In FIG. 21B, the n-type semiconductor layer 744 over the insulator layer 742 is etched using the wirings 754, 756, 758, and 760 as masks to form n-type semiconductor layers 762 and 764 that form a source region and a drain region.

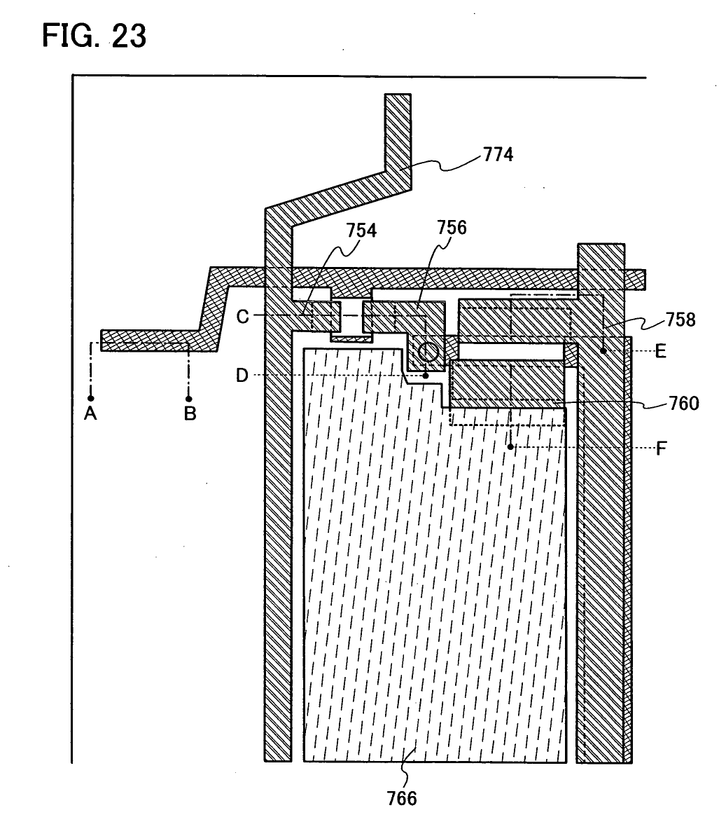

In FIG. 21C, a first electrode 766 corresponding to a pixel electrode is formed so as to be electrically connected to a wiring 772 by selectively discharging a composition containing a conductive material. Further, a plane structure taken along lines A-B, C-D, and E-F in a longitudinal structure of FIG. 21C is shown in FIG. 23.

The first electrode 766 is formed by a droplet discharging method. The first electrode 766 can be formed using a composition containing indium tin oxide (ITO), indium tin oxide containing silicon oxide, zinc oxide, tin oxide, or the like. Besides, conductive oxide in which indium oxide containing silicon oxide is mixed with 2 to 20% of zinc oxide (hereinafter, also referred to as “IZO”) may also be used. Then, a predetermined pattern is formed to form a pixel electrode by baking.

Moreover, the first electrode 766 may be formed using Ag (silver), Au (gold), Cu (copper), W (tungsten), Al (aluminum), or the like. In this case, light emitted from an EL layer is emitted in an opposite direction to a substrate 700.

Furthermore, a protection layer 768 formed from silicon nitride or silicon nitride oxide and an insulator layer 770 are formed over an entire surface. The insulator layer 770 is acceptable as long as it is an insulator which can be formed by a spin coating method, a dipping method, a printing method, or the like. The protection layer 768 and the insulator layer 770 are formed so as to cover an edge portion of the first electrode 766. A structure of the protection layer 768 and the insulator layer 770 shown in FIG. 21C can be formed by an etching process, and accordingly, a surface of the first electrode 766 is exposed. This etching is concurrently performed to the protection layer 768 and the gate insulating layer 728 that are below the insulator layer 770 so that the first electrode 766 and the gate wiring 720 are exposed.

The insulator layer 770 is formed to be provided with an opening of a through hole in accordance with a position where a pixel is formed corresponding to the first electrode 766. This insulator layer 770 can be formed using silicon oxide; silicon nitride; silicon oxynitride; aluminum oxide; aluminum nitride; aluminum oxynitride; other inorganic insulating materials; acrylic acid, methacrylic acid, and a derivative thereof; a heat-resistant high molecular compound such as polyimide, aromatic polyamide, or polybenzimidazole; an insulating material including a Si—O—Si bond of compounds containing silicon, oxygen, or hydrogen formed using a siloxane based material as a starting material; or an organic siloxane based insulating material in which hydrogen bonded to silicon is substituted by an organic group such as methyl or phenyl. When the insulator layer 770 is formed using a photosensitive or non-photosensitive material such as acrylic or polyimide, a side face of the insulator layer 770 has a shape in which a curvature radius changes continuously, and an upper layer thin film is formed without breaking, which is preferable.

By the above steps, an element substrate 800 for an EL display panel, over which a bottom gate type (also referred to as an inversely staggered type) TFT and the first electrode are connected to each other, is completed.

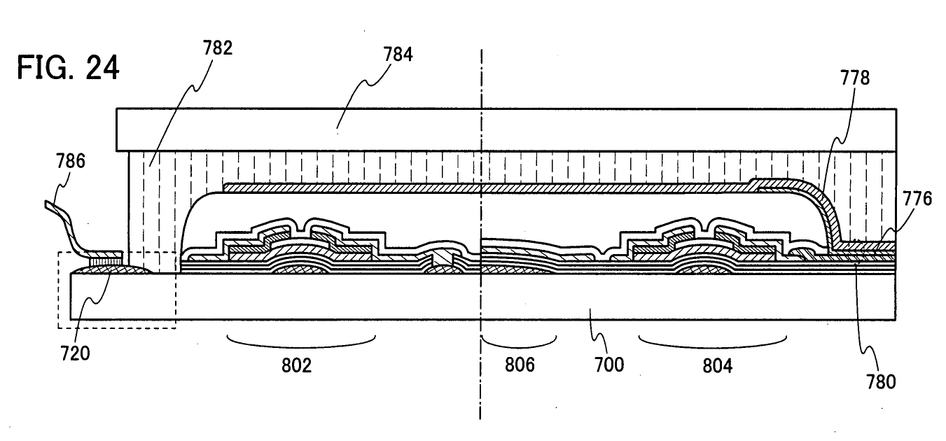

FIG. 24 shows a mode in which an EL layer 776 is formed over the element substrate 800 and a sealing substrate 784 is combined. Before forming the EL layer 776, heat treatment is performed at 100° C. or more in atmospheric pressure to remove moisture in the insulator layer 770 or attached to a surface thereof. In addition, it is preferable that heat treatment be performed under reduced pressure at 200 to 400° C., preferably 250 to 350° C., and without exposing to the air, the EL layer 776 be formed by a vacuum evaporation method or a droplet discharging method under reduced pressure. The EL layer described in Embodiment Mode 8 can be applied to the detail of the EL layer 776.

Subsequently, a sealing material 782 is formed and sealing is performed by using the sealing substrate 784. Thereafter, a flexible wiring substrate 786 may be connected to the gate wiring 720.

As described above, in this embodiment mode, a transistor can be manufactured without using a light exposure process using a photomask and a light-emitting device in which an EL element is combined can be manufactured. In this embodiment mode, all or part of processing such as resist application, exposure, or development that relate to a light exposure process can be omitted. In addition, by directly forming various patterns over a substrate by a droplet discharging method, an EL display panel can be easily formed even in a case of using a glass substrate of fifth generation or later having a side of longer than 1000 mm.

### Embodiment Mode 12

In this embodiment mode, an example of a light-emitting device which can be manufactured by the deposition devices described in Embodiment Modes 1 to 7 will be explained with reference to drawings. In particular, in this embodiment mode, a light-emitting device of which the manufacturing process includes a step of forming a predetermined pattern without using a photomask at least as part in a manufacturing process of an element substrate including a channel etch type transistor will be explained with reference to drawings.

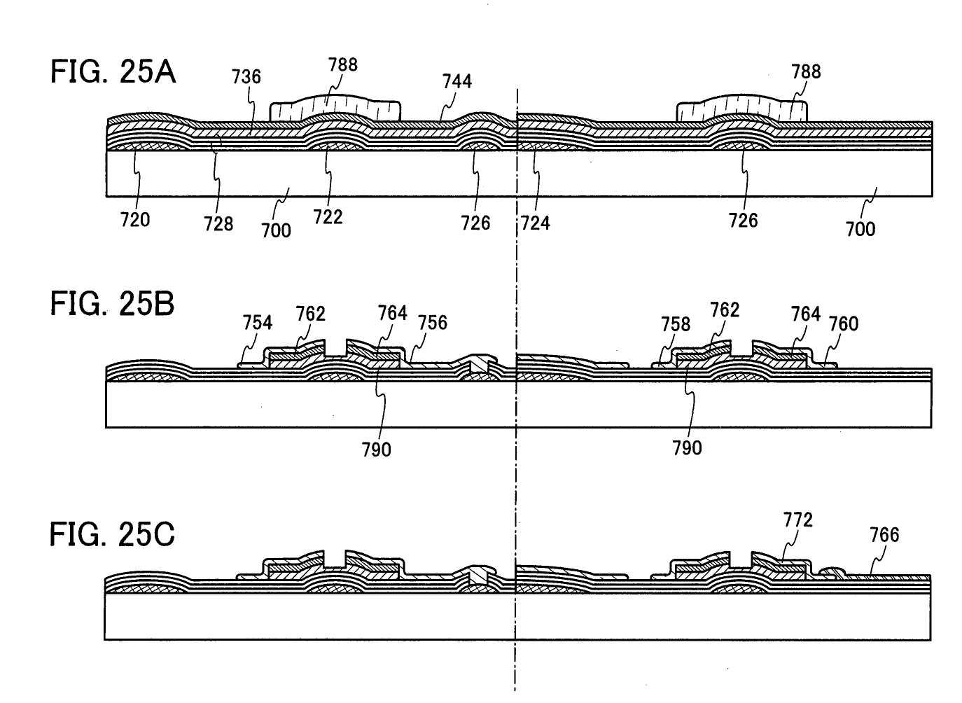

In FIG. 25A, a composition containing a conductive material is formed over a substrate 700 by a printing method to form a gate wiring 720, a gate electrode 722, a capacitor electrode 724, and a gate electrode 726. Then, a gate insulating layer 728 is formed to be a single layer or a stacked layer by a plasma CVD method or a sputtering method. The gate insulting layer 728 may be formed using silicon nitride or silicon oxide in the same manner as Embodiment Mode 11. Moreover, a semiconductor layer 736 serving as an active layer is formed.

An n-type semiconductor layer 744 is formed over the semiconductor layer 736. Next, a mask 788 is formed over the n-type semiconductor layer 744 by selectively discharging a resist composition. Subsequently, the semiconductor layer 736 and the n-type semiconductor layer 744 are etched by using the mask 788.

In FIG. 25B, the composition containing a conductive material is discharged in accordance with a position of the semiconductor layer which is separated by etching, to form wirings 754, 756, 758, and 760. The n-type semiconductor layer is etched by using the wirings as masks. N-type semiconductor layers 762 and 764 remaining in portions overlapped with the wirings 754, 756, 758, and 760 become layers including regions serving as a source or a drain. A semiconductor layer 790 includes a region for forming a channel, and is formed to be in contact with the n-type semiconductor layers 762 and 764. In addition, before the etching process, a through hole 752 is formed in part of the gate insulating layer 728 in the same manner as Embodiment Mode 11 and part of the gate electrode 726, which is placed below the layer, is exposed; accordingly, a connection structure between the wiring 756 and the gate electrode 726 can be formed.

In FIG. 25C, a first electrode 766 is formed so as to be electrically connected to the wiring 760 by discharging the composition containing a conductive material.

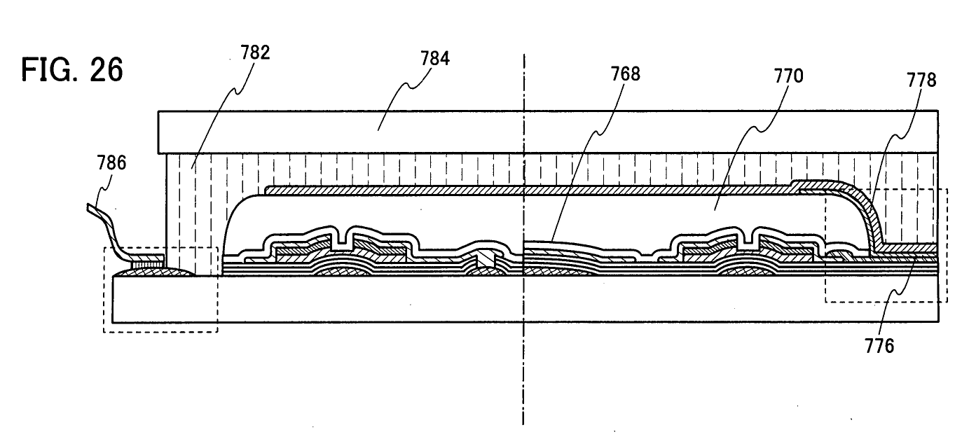

In FIG. 26, in the same manner as Embodiment Mode 11, a protection layer 768, an insulator layer 770, an EL layer 776, and a second electrode 778 are formed, and furthermore a sealing material 782 is formed, and sealing is performed using a sealing substrate 784. Thereafter, a flexible wiring substrate 786 may be connected to the gate wiring 720. Accordingly, a light-emitting device having a display function can be manufactured.

### Embodiment Mode 13

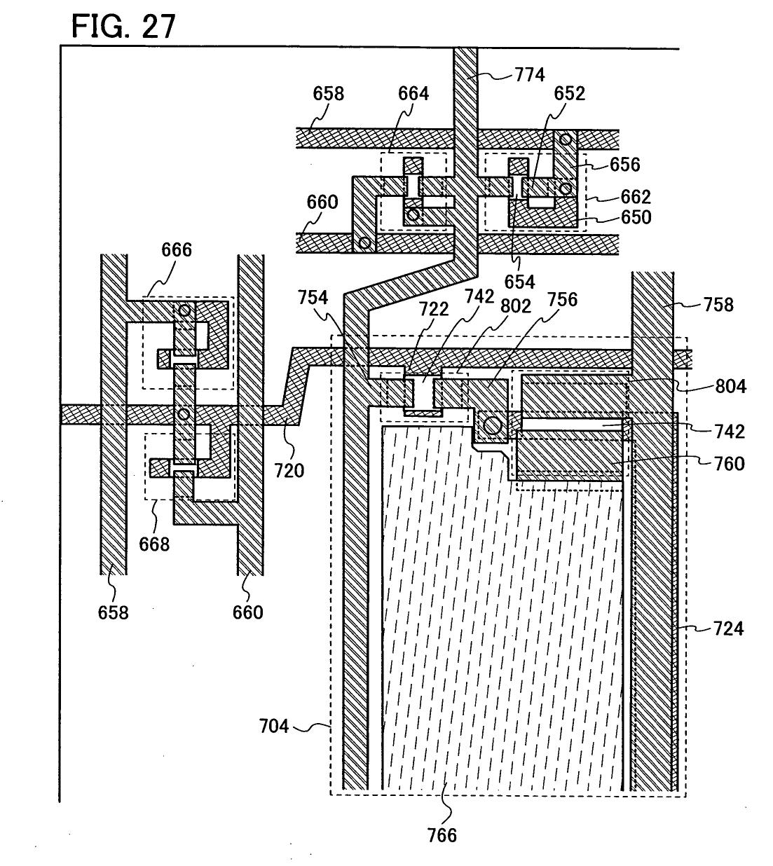

One mode of the display devices described in Embodiment Mode 11 and Embodiment Mode 12, in which a protection diode is provided in a scanning line input terminal portion and a signal line input terminal portion will be explained with reference to FIG. 27. In FIG. 27, a switching transistor 802, a driving transistor 804 and a capacitor 806 are provided in a pixel 704.

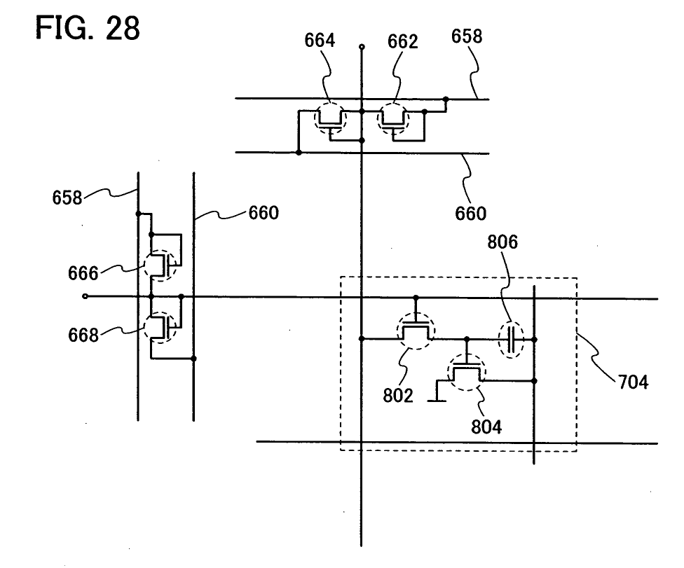

Protection diodes 662 and 664 are provided in the signal line input terminal portion. The protection diodes are manufactured in the same process as the switching transistor 802 or the driving transistor 804. A gate of the transistor is connected to a drain or a source, and accordingly each of the protection diodes 662 and 664 operates as a diode. It is to be noted that FIG. 28 shows an equivalent circuit of a top view shown in FIG. 27.

The protection diode 662 has a gate electrode 650, a semiconductor layer 652, a channel protection insulating layer 654, and a wiring 656. The protection diode 664 has a similar structure. Common potential lines 658 and 660 that are connected to the protection diode 662 are formed of the same layer as the gate electrode. Therefore, in order to be electrically connected to the wiring 656, a contact hole is required to be formed in a gate insulating layer.

The contact hole in the gate insulating layer may be processed with etching using a mask formed by a droplet discharging method. In this case, electric discharge machining can be performed locally when the etching process using atmospheric pressure discharge is performed, in which case a mask is not required to be formed over the entire surface of the substrate. A signal wiring 774 is formed of the same layer as a wiring 754 in the switching transistor 802, and has a structure in which the signal wiring 774 connected to the wiring 754 is connected to a source side or a drain side.

Protection diodes 666 and 668 in the input terminal portion on the scanning signal line side have a similar structure. As described above, protection diode provided for an input stage can be concurrently formed.

### Embodiment Mode 14

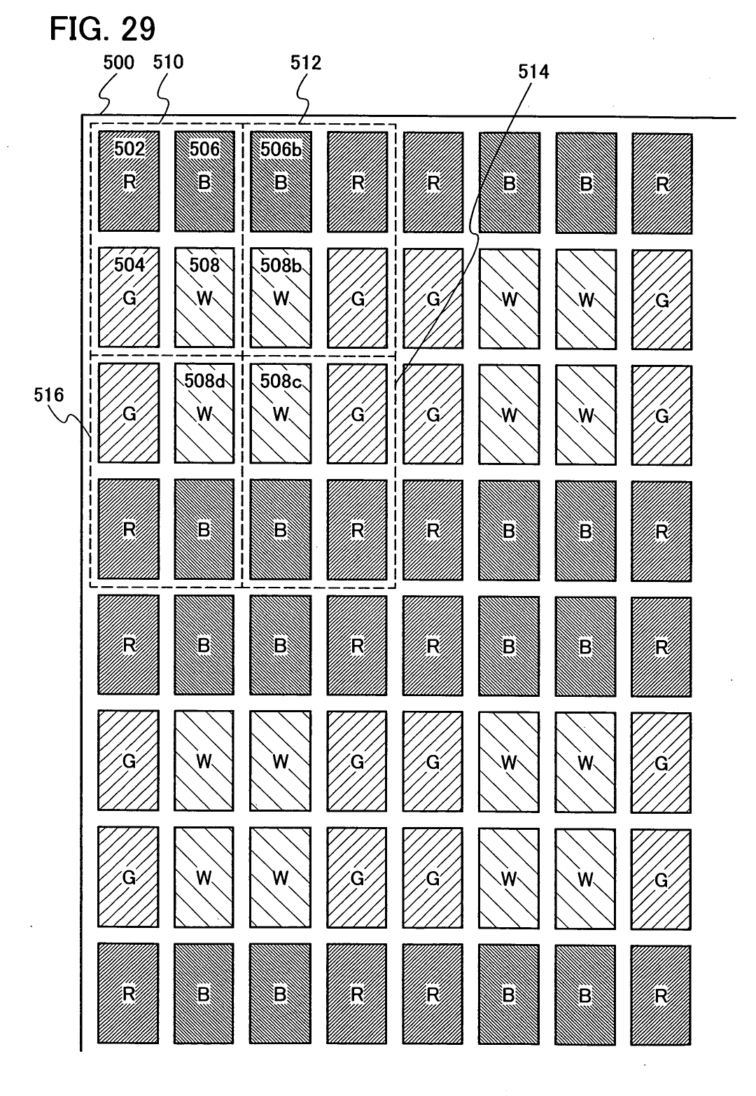

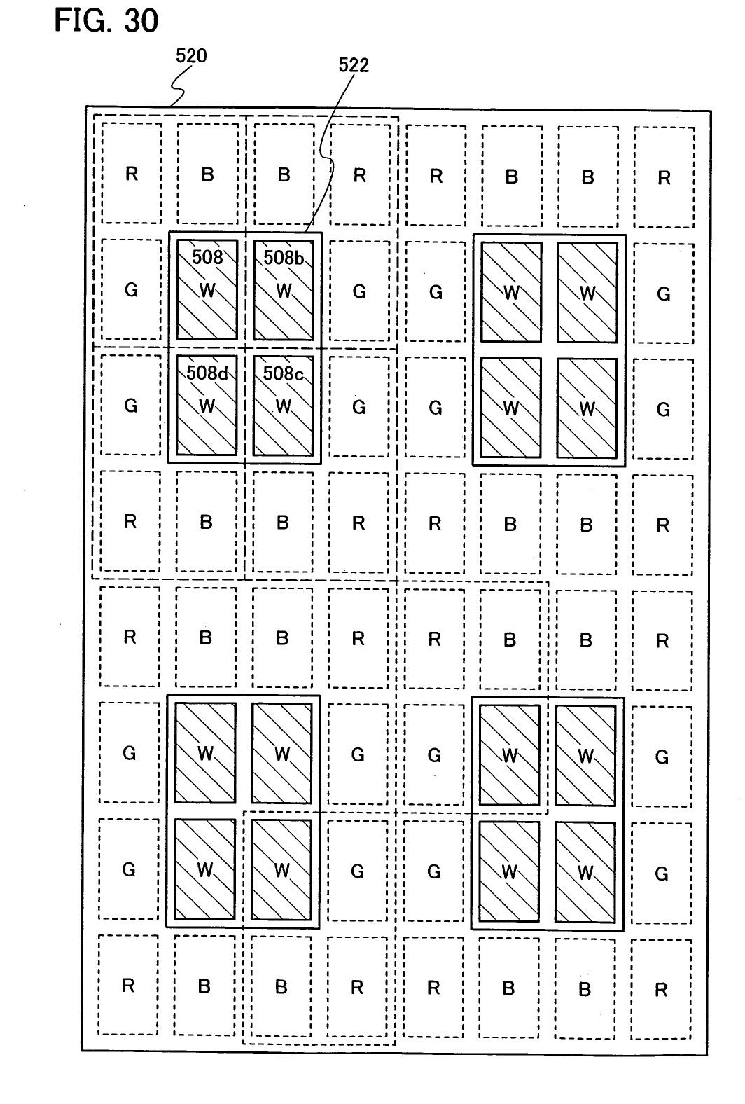

In this embodiment mode, an arrangement of pixels in a display portion of the light-emitting devices in Embodiment Modes 9 to 13, and an evaporation method of an EL layer corresponding to the pixel will be explained with reference to FIG. 29 and FIG. 30.

In FIG. 29, a display portion 500 has a dot 510 including a plurality of pixels with different light emission colors. A pixel (R) 502, a pixel (G) 504, a pixel (B) 506, and a pixel (W) 508 are included in the dot 510. The pixel (R) 502 is a pixel provided with an EL element which emits red light, the pixel (G) 504 is a pixel provided with an EL element which emits green light, the pixel (B) 506 is a pixel provided with an EL element which emits blue light, and the pixel (W) 508 is a pixel provided with an EL element which emits white light. It is to be noted that a combination of pixels described here is an example of a possible combination, and the dot 510 can be formed by a combination of various pixels, such as a structure in which pixels which emit three colors corresponding to so-called RGB color display are provided or a structure in which a complementary color is added thereto.

Although a dot 512 which is adjacent to the dot 510 includes a pixel (R), a pixel (G), a pixel (B), and a pixel (W) in the same way, an arrangement in the dot 512 is different from the one in the dot 510. That is, the pixel (B) 506 and the pixel (W) 508 of the dot 510 are arranged so as be adjacent to a pixel (B) 506b and a pixel (W) 508b of the dot 512, respectively. An arrangement of pixels in a dot 514 which is adjacent to the dot 512 is similar. In addition, an arrangement of pixels in a dot 516 which is adjacent to a pixel element 514 is also similar.

By arranging pixels as described above, a plurality of pixels of the same color can be assembled to be arranged. For example, in FIG. 29, the pixel (W) 508, the pixel (W) 508b, a pixel (W) 508c, and a pixel (W) 508d each belonging to a different dot are adjacent to each other to be arranged.

Each EL element included in the pixel (R) 502, the pixel (G) 504, the pixel (B) 506, and the pixel (W) 508 has a different structure of an EL layer. Specifically, a hole injecting layer, a hole transporting layer, an electron injecting layer, an electron transporting layer, or the like is common in each EL layer, and a material of a light-emitting element is different in each EL element.

When a display portion in which a plurality of pixels with different colors is arranged is formed, an EL layer can be formed using a shadow mask as described in Embodiment Mode 8. The shadow mask is provided with an opening in a region where a film is desired to be formed, and the opening is placed in accordance with an arrangement of pixels.

FIG. 30 shows an example of such a shadow mask. An opening 522 is formed in a shadow mask 520 in accordance with an arrangement of pixels. The opening 522 in the shadow mask 520 is arranged in accordance with the arrangement of the pixels in order to make a light-emitting layer different in each pixel depending on an emission color, for example. In FIG. 30, the opening 522 is arranged so as to be placed in the pixel (W) 508b, the pixel (W) 508c, and the pixel (W) 508d. In this case, by arranging pixels with the same emission color each belonging to a different pixel element to be adjacent to each other, the opening 522 can be made large. Consequently, the openings 522 are not required to be densely formed; accordingly, processing accuracy of the shadow mask 520 can be decreased so that miniaturization of pixels can be flexibly dealt with.

In addition, by such an arrangement of the pixels, a distance between arrangements of the pixels can be decreased. This is because a plurality of pixels emitting the same color can be placed in one opening 522 of the shadow mask 520.

When a light-emitting layer emitting a different color is formed, by displacing a position of the shadow mask 520, the same can be performed to the adjacent pixels.

By applying such an arrangement of pixels and a shadow mask corresponding to the arrangement to the deposition devices described in Embodiment Modes 1 to 7, deposition can be continuously performed with in-plane uniformity of an evaporation film even in a case of a large-sized glass substrate having a side of longer than 1000 mm. In addition, it is not necessary that the evaporation source is supplied with an evaporation material every time an evaporation material is used up; therefore, throughput can be improved.

### Embodiment Mode 15

In this embodiment mode, an example of a deposition method in forming a film by the deposition devices described in Embodiment Modes 1 to 7 will be described.

Although there is no limitations to a size of a substrate for forming a film such as an EL layer, for example, glass substrates of sixth generation having a size of 1500 mm×1800 mm, seventh generation having a size of 1870 mm×2200 mm, and eighth generation of 2160 mm×2400 mm can be applied as a substrate for a television having a large-sized screen. It is needless to say that a glass substrate of the following generations, that is a larger-sized glass substrate, can be applied.

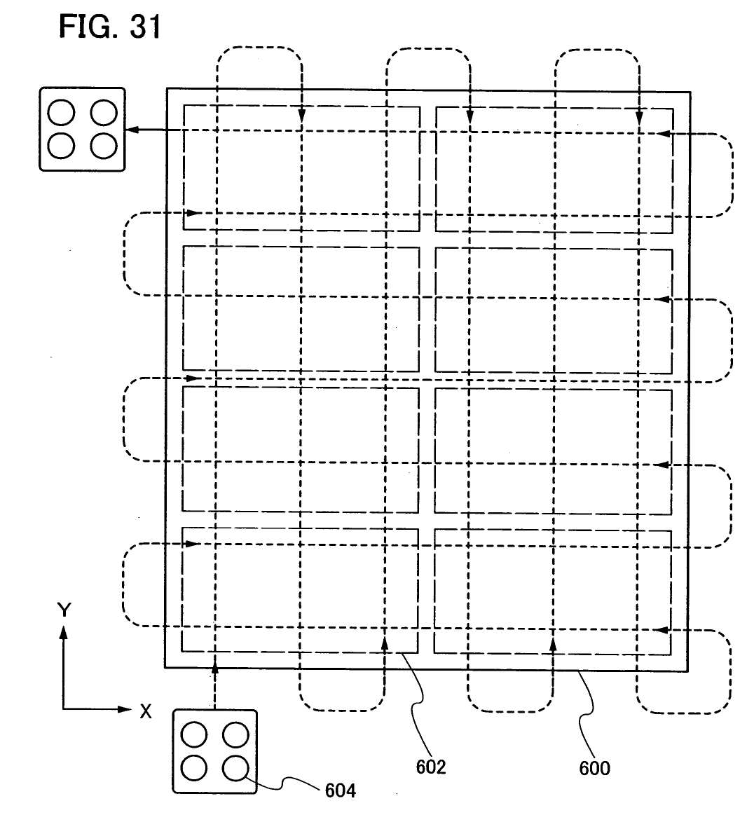

FIG. 31 shows a substrate 600 of an eighth generation having a size of 2160 mm×2400 mm in which eight 40-inch panels can be extracted, as an example. A plurality of element substrates 602 for each forming a screen of 40-inch-class is arranged in a substrate 600, for example.

With respect to such a substrate 600, an evaporation source 604 performs evaporation while moving so as to form a uniform evaporation film to at least a main surface over which the element substrate 602 is formed. The operation is shown by dotted line in FIG. 31. Reciprocation in one direction (Y direction) is performed, by displacing a scanning axis, to a main surface of the substrate 600. After deposition treatment of the main surface of the substrate 600 by such an operation of the evaporation source 604 is terminated, a similar scan may be further performed by changing a direction of reciprocation (X direction). As described above, by changing the scanning direction, uniformity of an evaporated film can be enhanced.

Although the scan by the evaporation source to the substrate is explained in this embodiment mode, a method in which the evaporation source is fixed and the substrate moves (Embodiment Mode 2) may be employed, and a method in which both the substrate and the evaporation source move (Embodiment Mode 3) may also be employed.

### Embodiment Mode 16

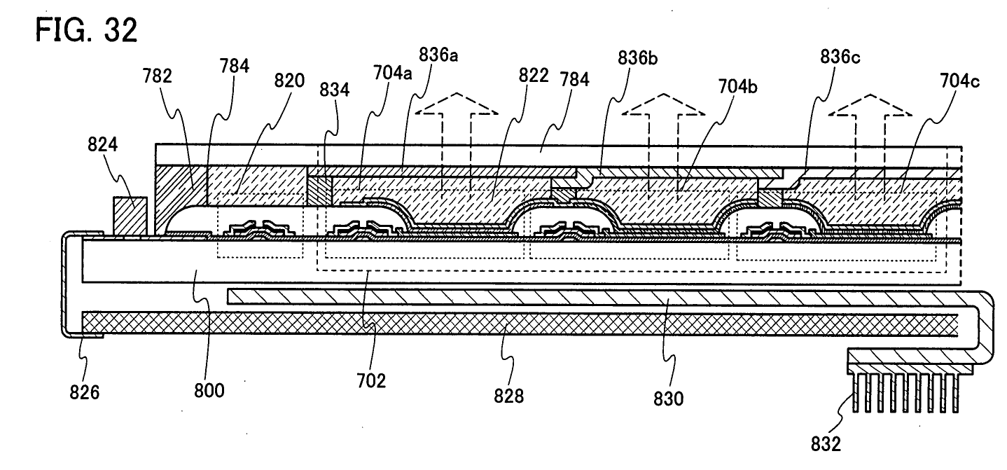

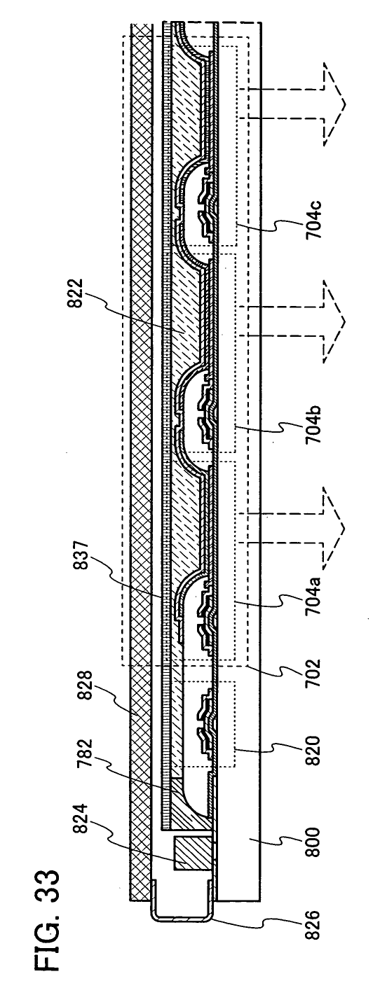

FIGS. 32 and 33 show an example of a module in which a driver circuit and the like are mounted over an element substrate 800 of Embodiment Modes 13, 14, and 15. In FIGS. 32 and 33, a pixel portion 702 including pixels 704a, 704b and 704c are formed over the element substrate 800.

In FIG. 32, a protection circuit 820 including a transistor which is similar to the one formed in the pixel or a diode which connects a gate to a source of the transistor is provided outside the pixel portion 702 and between a driver circuit 824 and the pixel 704. A driver IC formed using a single crystal semiconductor, a stick driver IC which is formed over a glass substrate by using a polycrystalline semiconductor, or the like can be applied to the driver circuit 824.

The element substrate 800 is attached to a sealing substrate 784, having a spacer 834 which is formed by a droplet discharging method therebetween. It is preferable that a spacer be formed in order to keep a distance between two substrates constant even in a case where a substrate is thin or an area of a pixel portion becomes larger. A space which is over an EL element 780 and between the element substrate 800 and the sealing substrate 784 may be filled with a light-transmissive resin material to be solidified, or may be filled with anhydrous nitrogen or an inert gas.

In FIG. 32, a case of a top emission structure of an EL element is shown, in which light is emitted in a direction of an arrow shown in the drawing. Multicolor display can be performed by making pixels 704a, 704b, and 704c emit light of different colors of red, green, and blue, respectively. In addition, by forming a coloring layer 836a, a coloring layer 836b, and a coloring layer 836c each of which corresponds to each color on the sealing substrate 784 side, color purity of light emitted to outside can be enhanced. Moreover, the coloring layers 836a, 836b, and 836c may be combined with the pixels 704a, 704b, and 704c as white EL elements.

An external circuit 828 is connected to a scanning line or a signal line connection terminal provided at an end of the element substrate 800 by a wiring substrate 826. In addition, a structure may be employed, in which a heat pipe 830 and a heat sink 832 are provided so as to be in contact with or adjacent to the element substrate 800 to enhance a heat dissipation effect.

It is to be noted that, although a top emission EL module is shown in FIG. 32, a bottom emission structure may also be used by changing a structure of the EL element or a position of an external circuit substrate.

FIG. 33 shows an example in which a sealing structure is formed by attaching a resin film 837 using a sealing material 782 or an adhesive resin 822 on a side where a pixel portion is formed over an element substrate 800. It is preferable to provide a gas barrier film for a surface of the resin film 837 in order to prevent water vapor from transmitting. Although a bottom emission structure in which light of an EL element is emitted through a substrate is shown in FIG. 33, a top emission structure may also be employed by making the resin film 837 or the adhesive resin 822 have a light-transmitting property. In either case, by using a film sealing structure, a display device can be further thinner and lighter.

### Embodiment Mode 17

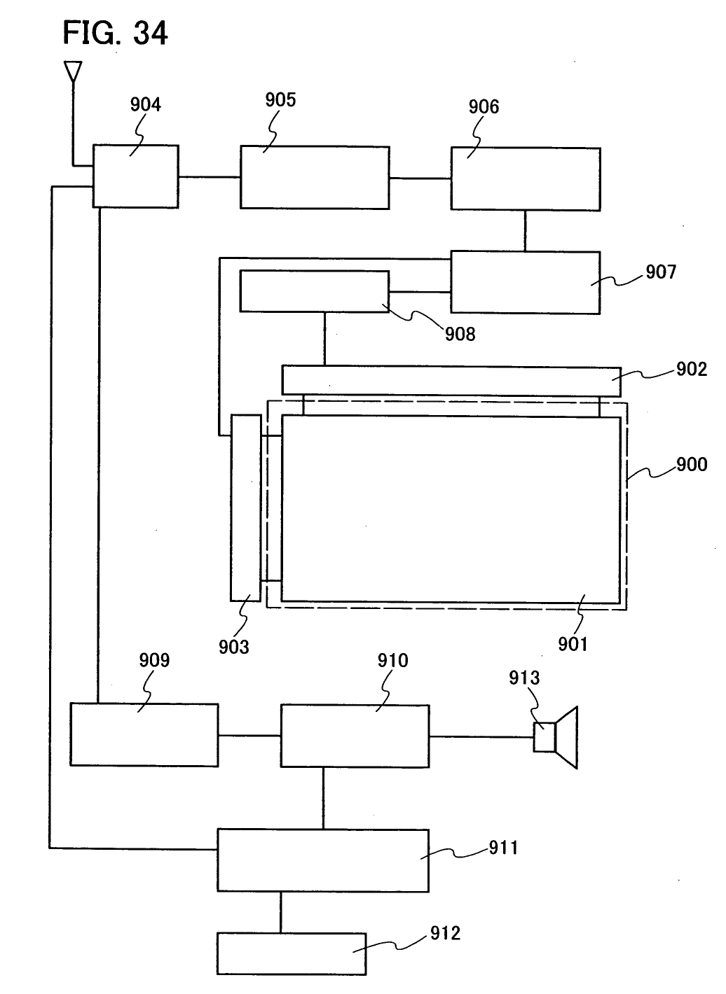

A television device can be completed by a module manufactured in Embodiment Mode 16. FIG. 34 shows a block diagram showing a main structure of the television device. A pixel portion 901 is formed over an element substrate 900. A signal line driver circuit 902 and a scanning line driver circuit 903 may be mounted on the element substrate 900 by a COG method.

As another external circuit, a video signal amplifier circuit 905 which amplifies a video signal among signals received by a tuner 904, a video signal processing circuit 906 which converts the signals outputted from the video signal amplifier circuit 905 into chrominance signals corresponding to respective colors of red, green, and blue, a control circuit 907 which converts the video signal into an input specification of the driver IC, and the like are provided on an input side of the video signal. The control circuit 907 outputs signals to both a scanning line side and a signal line side. In a case of digital driving, a signal dividing circuit 908 may be provided on the signal line side and an input digital signal may be divided into m pieces to be supplied.

An audio signal among signals received by the tuner 904 is sent to an audio signal amplifier circuit 909 and is supplied to a speaker 913 through an audio signal processing circuit 910. A control circuit 911 receives control information of a receiving station (reception frequency) or sound volume from an input portion 912 and transmits signals to the tuner 904 and the audio signal processing circuit 910.

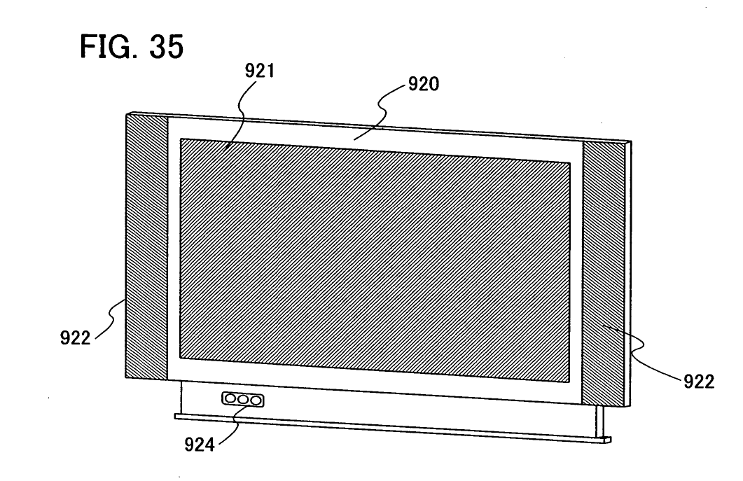

The television device can be completed by mounting such an external circuit and incorporating a module as explained in FIGS. 32 and 33 into a housing 920 as shown in FIG. 35. A display screen 921 is formed by using the module, and a speaker 922, operation switches 924, and the like are provided. Thus, a television device can be completed by the present invention.

It is needless to say that the invention is not limited to the television device, and can be applied to various use applications as a large-area display medium such as an information display board at a train station, an airport, or the like, or an advertisement display board on the street, as well as a monitor of a personal computer.

### Embodiment Mode 18

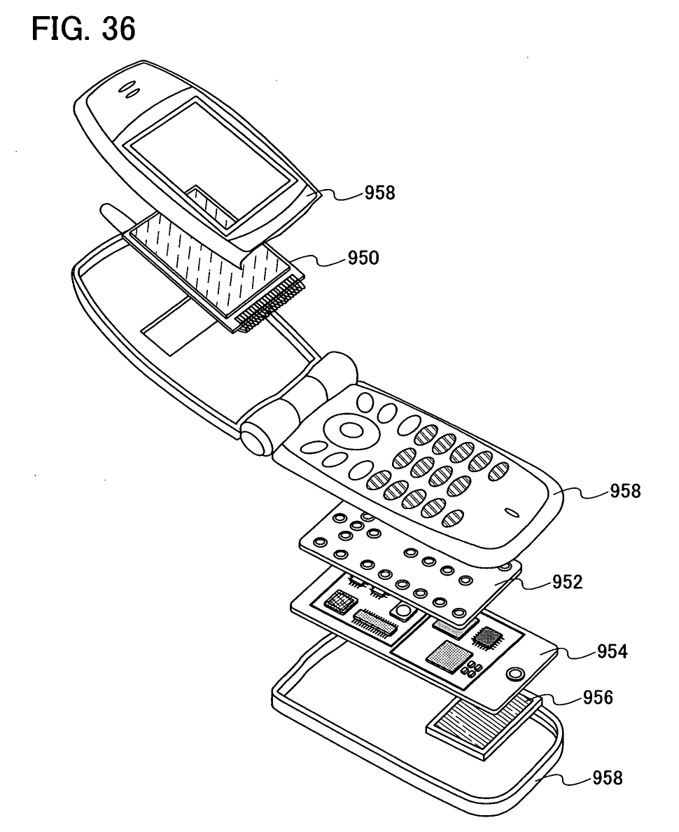

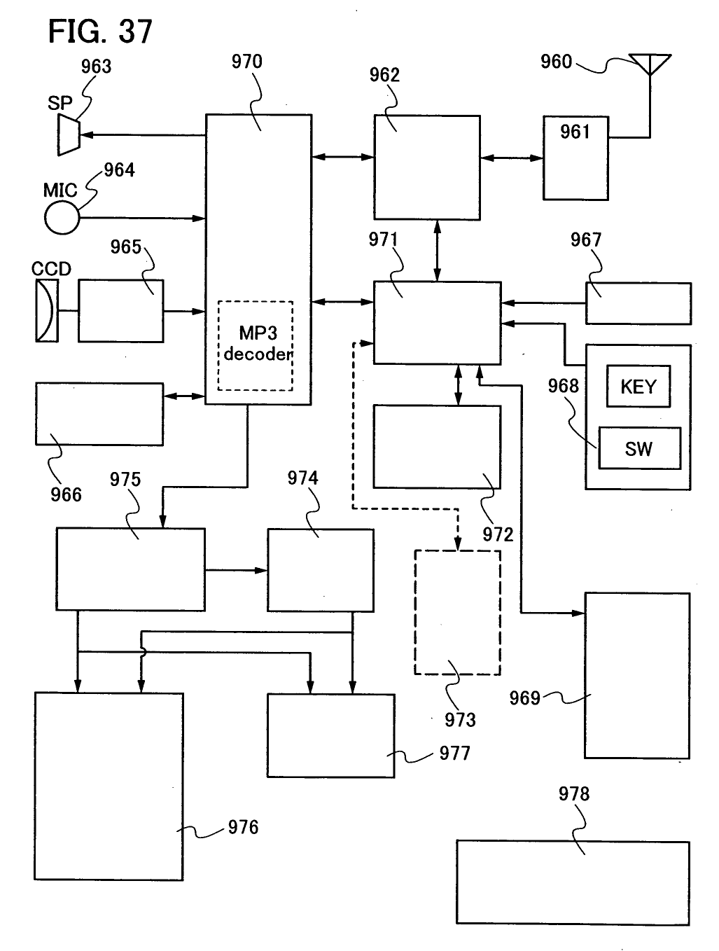

In this embodiment mode, an example of a cellular phone in which any one of display modules described in Embodiment Modes 1 to 9 is used will be explained with reference to FIGS. 36 and 37.

FIG. 36 is a view showing an assembly of a cellular phone. The cellular phone has a module 950, a key input switch 952, a circuit substrate 954, a secondary battery 956 that are placed in a housing 958. As shown in FIG. 36, cutting is performed to the housing 958 in accordance with a position of a display portion in placing the module 950. In addition, an IC chip or a sensor chip is mounted on the module 950.

An example of a structure of such a cellular phone is shown in FIG. 37. An antenna 960, a high frequency circuit 961, a base band processor 962, and the like include a communication circuit, a modulation circuit, a demodulation circuit, or the like for performing wireless communication of 700 to 900 MHz, and 1.7 to 2.5 GHz. An audio and image processing processor 970 communicates with a CPU 971 to transmit a video signal or the like to a controller 975, and in addition, controls a power supply circuit 974, outputs audio to a speaker 963, inputs audio from a microphone 964, processes image data transmitted from a CCD module 965, and the like. This image data may be stored in a memory card via an auxiliary memory input interface 966 (a memory card). The controller 975 transmits signals to a (main) display panel 976 and a (sub) display panel 977 and also switches a display.

The CPU 971 receives a signal from a light sensor 967 which detects outside light intensity and a key input switch 968 and controls the audio and image processing processor 970. In addition, the CPU controls communication which uses a local area network via a communication interface 969 (input and output IF (LAN/IR communication/USB/Bluetooth)). A memory 972 is provided to store information such as a phone number or sent/received e-mail. A memory medium 973 such as a hard disk may be added in order to further increase storage capacity. A power supply circuit 978 supplies power to these systems.

It is to be noted that FIG. 36 shows an example of an external appearance shape of the cellular phone, and the cellular phone relating to this embodiment mode can be modified in various modes in accordance with its function or use application.

Although a cellular phone is exemplified in this embodiment mode as described above, the present invention is not limited thereto, and various electronic devices provided with a module such as a computer and a video camera can be realized. For example, an electronic book, a portable information terminal (such as PDA (personal digital assistant)), a portable video game machine, a home video game machine, a navigation system, or the like is given.

This application is based on Japanese Patent Application serial No. 2005-258558 filed in Japan Patent Office on Sep. 6, 2005, the entire contents of which are hereby incorporated by reference.

What is claimed is:

1. A deposition device comprising:
a treatment chamber capable of keeping a reduced pressure state;
an evaporation source which is provided in the treatment chamber and is opposite to a substrate to be deposited with an evaporation material;
a mechanism for moving the evaporation source in the treatment chamber relative to the substrate;
a material supply source for supplying the evaporation material; and
a material supply tube for connecting the material supply source to the evaporation source.

2. A deposition device according to claim 1, wherein a plurality of the evaporation sources are provided.

3. A deposition device according to claim 1, wherein the material supply source continuously supplies the evaporation material to the evaporation source.

4. A deposition device comprising:
a treatment chamber capable of keeping a reduced pressure state;
an evaporation source which is provided in the treatment chamber and is opposite to a substrate to be deposited with an evaporation material, for aerosolizing material liquid in which the evaporation material is dissolved or dispersed in a solvent to evaporate or sublimate the solvent;
a mechanism for moving the evaporation source in the treatment chamber relative to the substrate;
a material supply portion for supplying the material liquid; and
a material supply tube for connecting the material supply portion to the evaporation source.

5. A deposition device according to claim 4, wherein a plurality of the evaporation sources are provided.

6. A deposition device according to claim 4, wherein the material supply portion continuously supplies the material liquid to the evaporation source.

7. A deposition device comprising:
a treatment chamber capable of keeping a reduced pressure state;
an evaporation source which is provided in the treatment chamber and is opposite to a substrate to be deposited with an evaporation material, for evaporating or sublimating a powdery evaporation material with an inert gas or a reactive gas;
a mechanism for moving the evaporation source in the treatment chamber relative to the substrate;
a material supply portion for supplying the powdery evaporation material with the active gas or the reactive gas; and
a material supply tube for connecting the material supply portion to the evaporation source.

8. A deposition device according to claim 7, wherein a plurality of the evaporation sources are provided.

9. A deposition device according to claim 7, wherein the material supply portion continuously supplies the powdery evaporation material to the evaporation source.

10. A deposition device comprising:
a treatment chamber capable of keeping a reduced pressure state;
an evaporation source which is provided in the treatment chamber and is opposite to a substrate to be deposited with an evaporation material, for evaporating or sublimating a powdery evaporation material;
a mechanism for moving the evaporation source in the treatment chamber relative to the substrate; and
a material supply portion in which a material supply tube is connected to the evaporation source,
wherein the powdery evaporation material is continuously supplied by rotating a screw provided in the material supply tube.

11. A deposition device according to claim 10, wherein a plurality of the evaporation sources are provided.

12. A deposition device according to claim 10, wherein the material supply portion continuously supplies the powdery evaporation material to the evaporation source.

13. A deposition device comprising:
a treatment chamber capable of keeping a reduced pressure state;
an evaporation source which is provided in the treatment chamber and is provided with an opening through which a flexible film to which an evaporation material is attached is continuously discharged;
an energy beam supply source for irradiating a portion of the flexible film to which the evaporation material is attached with an energy beam, the portion being exposed at the opening; and
a mechanism for moving the evaporation source in the treatment chamber relative to the substrate.

14. A deposition device according to claim 13, wherein a plurality of the evaporation sources are provided.

15. A method for manufacturing a display device comprising:
providing an evaporation source in a treatment chamber;
disposing a substrate in the treatment chamber; and
evaporating a material from the evaporation source to deposit the material over the substrate wherein the relative position of the evaporation source is repeatedly moved with respect to the substrate during the evaporation of the material;
wherein a material supply portion is connected to the evaporation source through a material supply tube.

16. A method for manufacturing a display device according to claim 15, wherein a plurality of the evaporation sources are provided.

17. A method for manufacturing a display device according to claim 15, wherein the material supply portion continuously supplies the material to the evaporation source.

18. A method for manufacturing a display device according to claim 15, wherein the material in a powdery form is transferred with an inert gas or a reactive gas from the material supply portion.

19. A method for manufacturing a display device according to claim 15, wherein the material in which an evaporation material is dissolved or dispersed in a solvent is transferred from the material supply portion.

20. A method for manufacturing a display device according to claim 15, wherein the material in a powdery form is transferred by rotating a screw in the material supply tube.
